(19) United States
(12) Patent Application Publication
(10) Pub. No.: US 2026/0262497 A1
(43) Pub. Date: Sep. 3, 2026

(54) SEMICONDUCTOR DEVICE AND VEHICLE

(71) Applicant: ROHM CO., LTD., Kyoto-shi (JP)

(72) Inventors: Yoshihisa TSUKAMOTO, Kyoto-shi (JP); Masashi HAYASHIGUCHI, Kyoto-shi (JP); Hidetoshi ABE, Kyoto-shi (JP); Hideki SAWADA, Kyoto-shi (JP)

(21) Appl. No.: 19/655,999

(22) Filed: Apr. 23, 2026

Related U.S. Application Data
(63) Continuation of application No. PCT/JP2024/037554, filed on Oct. 22, 2024.

(30) Foreign Application Priority Data
Oct. 30, 2023 (JP) 2023-185235

(51) Int. Cl. H10W 40/47; H02M 7/00; H05K 7/20; H10W 40/20; H10W 40/22; H10W 70/20; H10W 72/30; H10W 90/00; H10W 90/10

(52) U.S. Cl. CPC H10W 40/47; H02M 7/003; H05K 7/20927; H10W 40/226; H10W 40/235; H10W 40/242; H10W 70/24; H10W 72/334; H10W 72/365; H10W 90/737; H10W 72/322; H10W 90/10; H10W 90/767

(57) ABSTRACT

A semiconductor device includes a first terminal, a second terminal, a first semiconductor element, and a first heat dissipation member. The second terminal is positioned on one side in a first direction from the first terminal. The first semiconductor element is positioned opposite the second terminal with respect to the first terminal. The first semiconductor element is electrically connected to the first terminal. The first heat dissipation member is connected to the first terminal. A first flow path is provided between the first terminal and the second terminal in the first direction. The first heat dissipation member is accommodated in the first flow path.

### TECHNICAL FIELD

The present disclosure relates to a semiconductor device and a vehicle equipped with the semiconductor device.

### BACKGROUND ART

WO 2017/094370 discloses an example of a semiconductor module that is equipped with a semiconductor device and a cooling unit. The cooling unit includes a housing having a hollow region and a heat dissipator. The housing is formed with an opening that leads into the hollow region. The heat dissipator is attached to the housing to cover the opening. The heat dissipator is partially housed in the hollow region. The semiconductor device is bonded to a portion of the heat dissipator that extends outward from the hollow region. When a coolant (such as cooling water) flows into the hollow region, the coolant comes into contact with the heat dissipator. In this way, the semiconductor device is cooled efficiently through the heat dissipator.

However, in the configuration of the semiconductor module disclosed in WO 2017/094370, a sufficient cooling effect for the semiconductor device is not achieved relative to the size of the cooling unit.

### BRIEF DESCRIPTION OF THE DRAWINGS

FIG. 1 is a plan view showing a semiconductor device according to a first embodiment of the present disclosure.

FIG. 2 is a plan view corresponding to FIG. 1, in which a housing is shown as transparent.

FIG. 3 is a plan view corresponding to FIG. 2, in which a fourth terminal and a plurality of fourth heat dissipation members are omitted.

FIG. 4 is a plan view corresponding to FIG. 3, in which a second terminal, a conductive member, a third signal terminal, a fourth signal terminal, a plurality of second semiconductor elements, a plurality of second spacers, a plurality of third leads, and a plurality of fourth leads are omitted.

FIG. 5 is a plan view corresponding to FIG. 4, in which a first terminal and a plurality of first heat dissipation members are omitted.

FIG. 6 is a bottom view showing the semiconductor device in FIG. 1.

FIG. 7 is a cross-sectional view along line VII-VII in FIG. 3.

FIG. 8 is a cross-sectional view along line VIII-VIII in FIG. 3.

FIG. 9 is a cross-sectional view along line IX-IX in FIG. 3.

FIG. 10 is a partially enlarged view of FIG. 8, showing one of a plurality of first semiconductor elements and the vicinity of the first semiconductor element.

FIG. 11 is a partially enlarged view of FIG. 8, showing one of the second semiconductor elements and the vicinity of the second semiconductor element.

FIG. 12 is a cross-sectional view showing the state where a coolant flows downward in the semiconductor device of FIG. 1.

FIG. 13 is a partially enlarged cross-sectional view showing a semiconductor device according to a first variation of the first embodiment in the present disclosure.

FIG. 14 is a partially enlarged cross-sectional view showing a semiconductor device according to a second variation of the first embodiment in the present disclosure.

FIG. 15 is a partially enlarged cross-sectional view showing a semiconductor device according to a third variation of the first embodiment in the present disclosure.

FIG. 16 is a schematic view showing a vehicle equipped with the semiconductor device in FIG. 1.

FIG. 17 is a cross-sectional view showing a semiconductor device according to a second embodiment of the present disclosure, and corresponds to FIG. 7.

FIG. 18 is a cross-sectional view showing the semiconductor device in FIG. 17, and corresponds to FIG. 8.

FIG. 19 is a plan view showing a semiconductor device according to a third embodiment of the present disclosure, and corresponds to FIG. 3.

FIG. 20 is a cross-sectional view along line XX-XX in FIG. 19.

FIG. 21 is a cross-sectional view along line XXI-XXI in FIG. 19.

FIG. 22 is a partially enlarged view of FIG. 21.

FIG. 23 is a partially enlarged cross-sectional view showing a semiconductor device according to a variation of the third embodiment in the present disclosure.

FIG. 24 is a cross-sectional view showing a semiconductor device according to a fourth embodiment of the present disclosure, and corresponds to FIG. 7.

FIG. 25 is a cross-sectional view showing the semiconductor device in FIG. 24, and corresponds to FIG. 8.

FIG. 26 is a plan view showing a semiconductor device according to a fifth embodiment of the present disclosure, and corresponds to FIG. 3.

FIG. 27 is a plan view showing the semiconductor device in FIG. 26, and corresponds to FIG. 5.

FIG. 28 is a cross-sectional view along line XXVIII-XXVIII in FIG. 26.

FIG. 29 is a cross-sectional view showing a semiconductor device according to a sixth embodiment of the present disclosure, and corresponds to FIG. 7.

FIG. 30 is a cross-sectional view showing the semiconductor device in FIG. 29, and corresponds to FIG. 8.

FIG. 31 is a partially enlarged view of FIG. 30.

FIG. 32 is a partially enlarged cross-sectional view showing a semiconductor device according to a variation of the sixth embodiment in the present disclosure.

FIG. 33 is a plan view showing a semiconductor device according to a seventh embodiment of the present disclosure, and corresponds to FIG. 4.

FIG. 34 is a cross-sectional view along line XXXIV-XXXIV in FIG. 33.

FIG. 35 is a cross-sectional view along line XXXV-XXXV in FIG. 33.

FIG. 36 is a plan view showing a semiconductor device according to an eighth embodiment of the present disclosure.

FIG. 37 is a bottom view showing the semiconductor device in FIG. 36.

FIG. 38 is a cross-sectional view along line XXXVIII-XXXVIII in FIG. 36.

FIG. 39 is a cross-sectional view along line XXXIX-XXXIX in FIG. 36.

FIG. 40 is a plan view showing a semiconductor device according to a ninth embodiment of the present disclosure, and corresponds to FIG. 3.

FIG. 41 is a plan view showing the semiconductor device in FIG. 40, and corresponds to FIG. 5.

FIG. 42 is a cross-sectional view along line XLII-XLII in FIG. 40.

FIG. 43 is a cross-sectional view along line XLIII-XLIII in FIG. 40.

FIG. 44 is a partially enlarged view of FIG. 42, showing one of a plurality of first semiconductor elements and the vicinity of the first semiconductor element.

FIG. 45 is a partially enlarged view of FIG. 42, showing one of a plurality of second semiconductor elements and the vicinity of the second semiconductor element.

FIG. 46 is a plan view showing a semiconductor device according to a tenth embodiment of the present disclosure.

FIG. 47 is a plan view showing the semiconductor device in FIG. 46, and corresponds to FIG. 2.

FIG. 48 is a plan view showing the semiconductor device in FIG. 46, and corresponds to FIG. 3.

FIG. 49 is a plan view showing the semiconductor device in FIG. 46, and corresponds to FIG. 5.

FIG. 50 is a cross-sectional view along line L-L in FIG. 47.

FIG. 51 is a cross-sectional view along line LI-LI in FIG. 47.

### DETAILED DESCRIPTION OF EMBODIMENTS

Details of the present disclosure will be described with reference to the accompanying drawings.

### First Embodiment

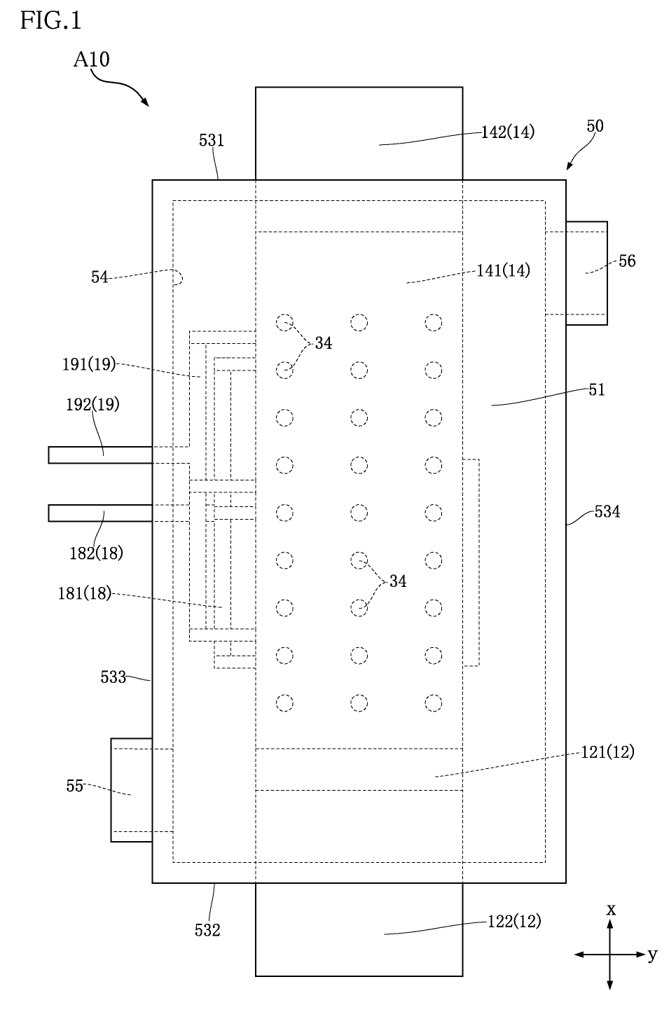

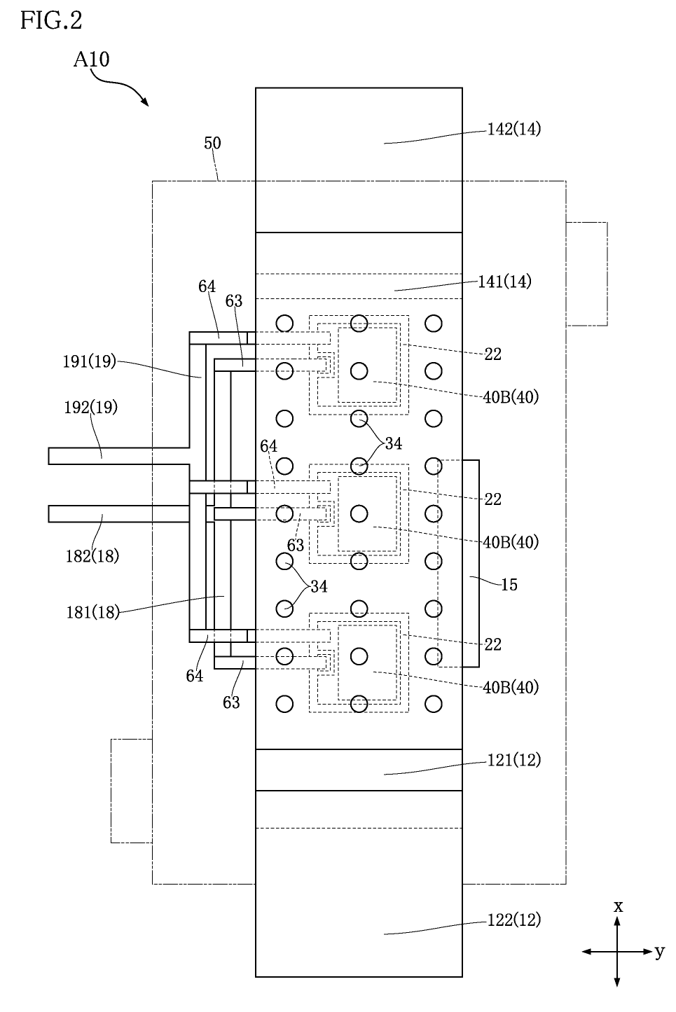

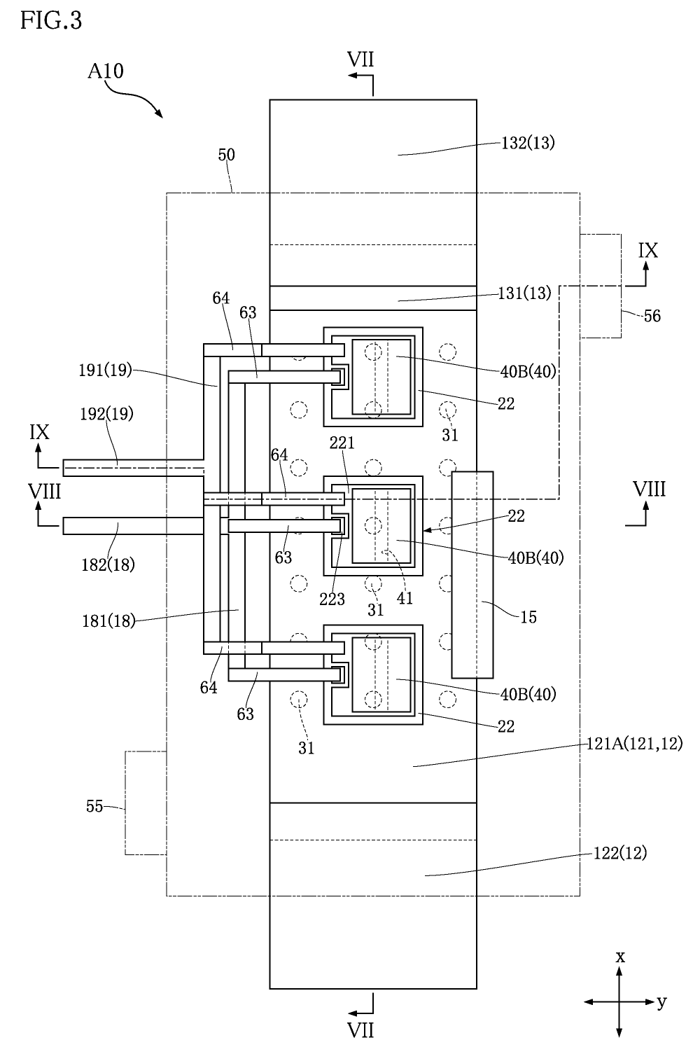

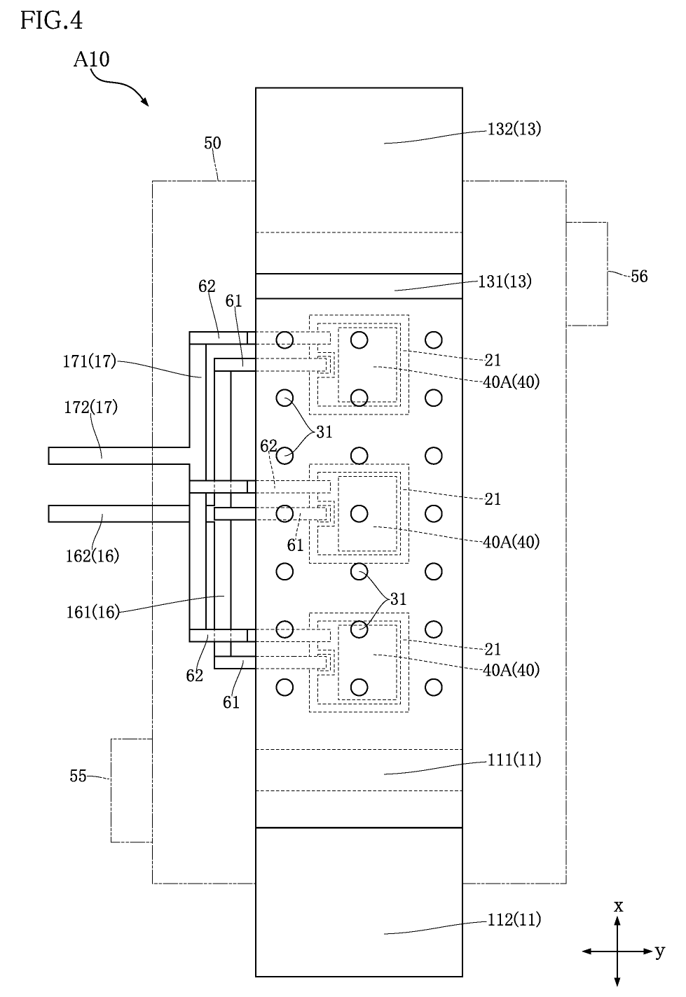

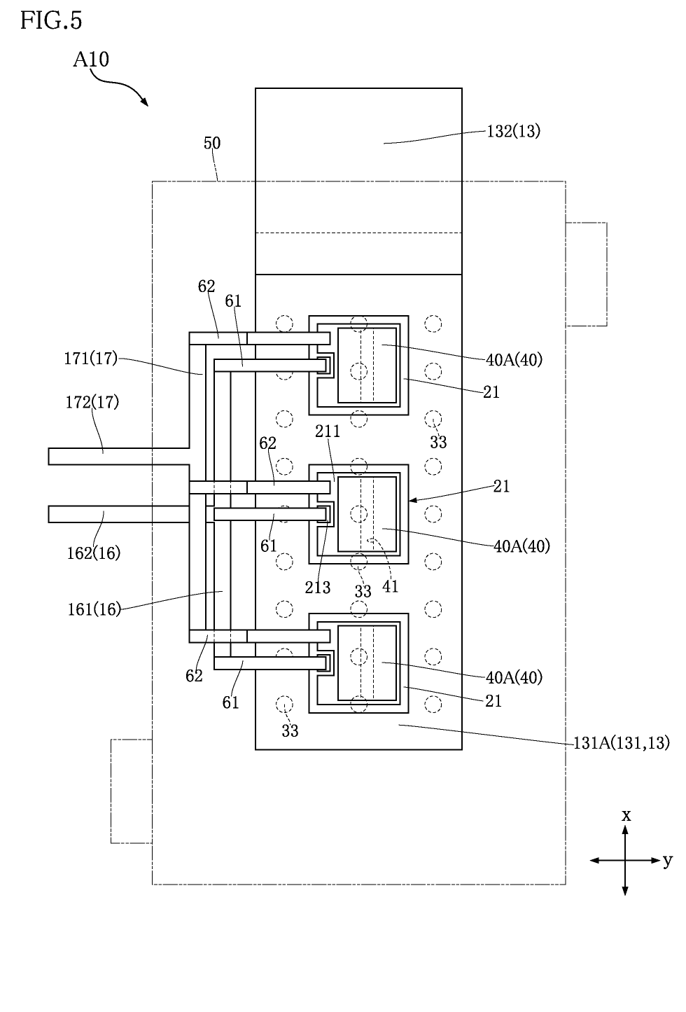

The following describes a semiconductor device A10 according to a first embodiment of the present disclosure, with reference to FIGS. 1-12. The semiconductor device A10 is typically used in a power conversion circuit, such as an inverter. The semiconductor device A10 includes a first terminal 11, a second terminal 12, a third terminal 13, a fourth terminal 14, a conductive member 15, a plurality of first semiconductor elements 21, a plurality of second semiconductor elements 22, a plurality of first heat dissipation members 31, a plurality of third heat dissipation members 33, a plurality of fourth heat dissipation members 34, a plurality of spacers 40, and a housing 50. The spacers 40 include a plurality of first spacers 40A and a plurality of second spacers 40B. The semiconductor device A10 further includes a first signal terminal 16, a second signal terminal 17, a third signal terminal 18, a fourth signal terminal 19, a plurality of first leads 61, a plurality of second leads 62, a plurality of third leads 63, and a plurality of fourth leads 64. For convenience of understanding, FIGS. 2- 5 show the housing 50 as transparent. FIGS. 2-5 show the housing 50 with imaginary lines (two-dot chain lines). For convenience of understanding, FIG. 3 omits the fourth terminal 14 and the fourth heat dissipation members 34 that are shown in FIG. 2. For convenience of understanding, FIG. 4 omits the second terminal 12, the conductive member 15, the third signal terminal 18, the fourth signal terminal 19, the second semiconductor elements 22, the second spacers 40B, the third leads 63, and the fourth leads 64 that are shown in FIG. 3. For convenience of understanding, FIG. 5 omits the first terminal 11 and the first heat dissipation members 31 that are shown in FIG. 4.

For convenience in the description of the semiconductor device A10, the direction normal to a first mounting surface 131A (described below) of the third terminal 13 will be referred to as "first direction z". A direction perpendicular to the first direction z will be referred to as "second direction x". The direction perpendicular to both of the first direction z and the second direction x will be referred to as "third direction y".

The semiconductor device A10 is configured with a half-bridge circuit including the first semiconductor elements 21 and the second semiconductor elements 22. The semiconductor device A10 uses the first semiconductor elements 21 and the second semiconductor elements 22 to convert the DC power supplied to the third terminal 13 and the fourth terminal 14 into AC power. The third terminal 13 is a P terminal (positive electrode). The fourth terminal 14 is an N terminal (negative electrode). The AC power generated by the conversion is inputted from the first terminal 11 and the second terminal 12 to a load, such as a motor.

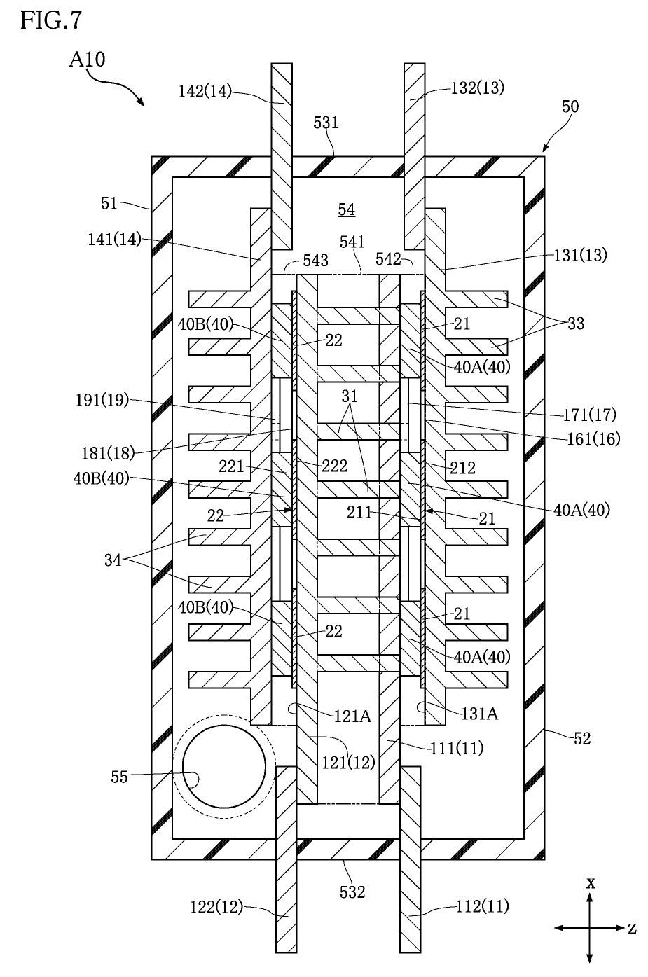

As shown in FIGS. 7-9, the housing 50 supports the first terminal 11, the second terminal 12, the third terminal 13, the fourth terminal 14, the first signal terminal 16, the second signal terminal 17, the third signal terminal 18, and the fourth signal terminal 19. The housing 50 is made of an insulating material containing resin. Alternatively, the housing 50 may be made of a conductive material containing a metal such as aluminum (Al).

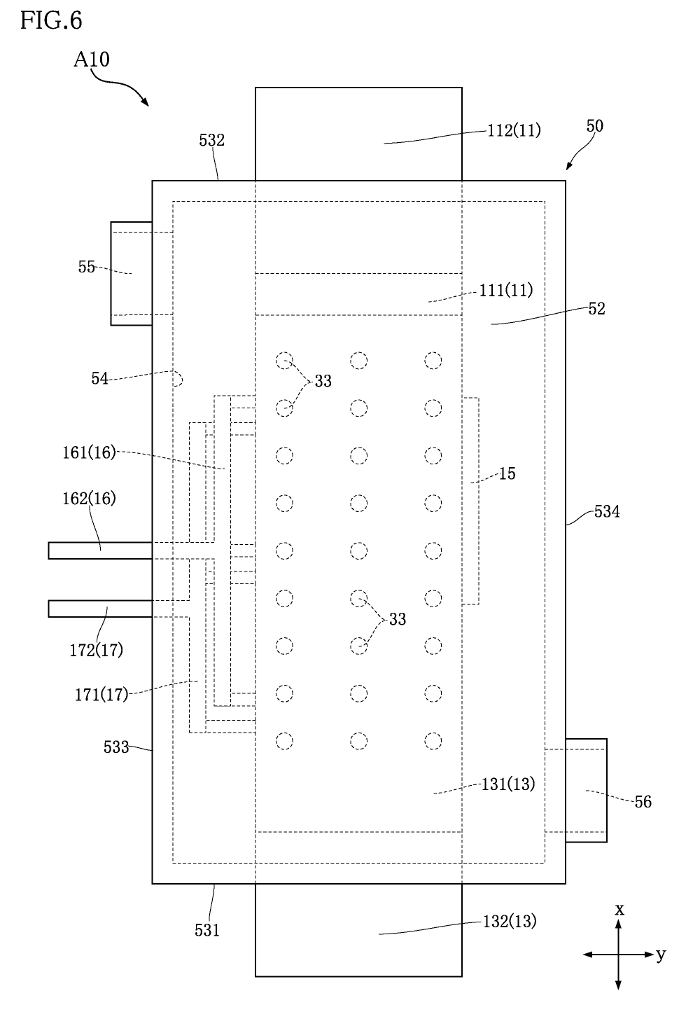

As shown in FIGS. 1 and 6, the housing 50 has a top surface 51, a bottom surface 52, a first side surface 531, a second side surface 532, a third side surface 533, and a fourth side surface 534. The top surface 51 faces one side in the first direction z. The bottom surface 52 faces away from the top surface 51 in the first direction z. The first side surface 531 and the second side surface 532 face away from each other in the second direction x. The third side surface 533 and the fourth side surface 534 face away from each other in the third direction y.

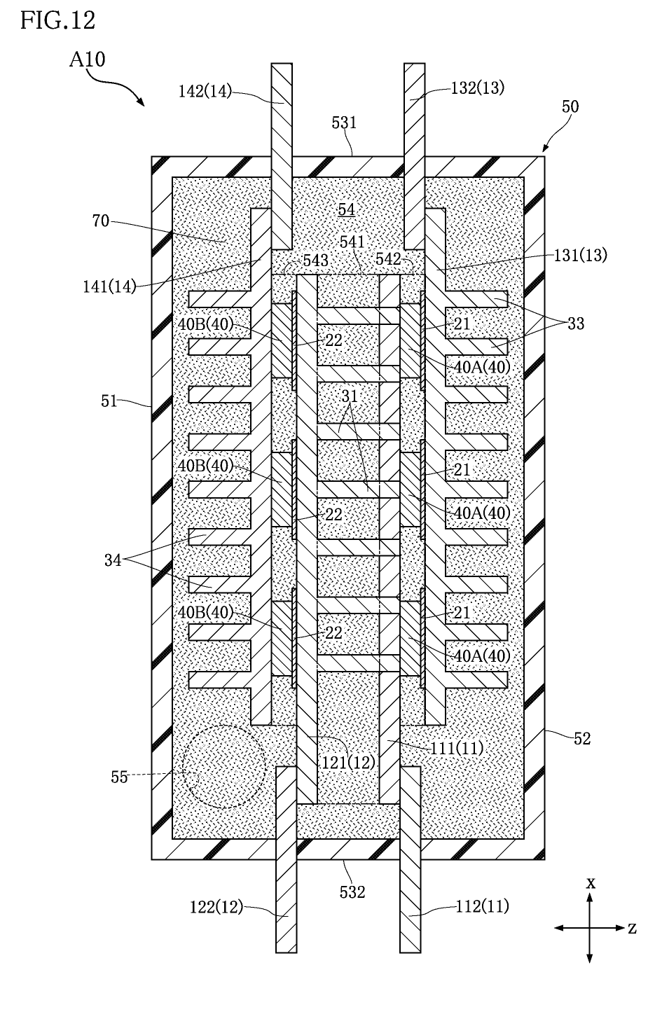

As shown in FIGS. 7-9, the housing 50 has a cavity 54. The cavity 54 is in communication with ambient air. Alternatively, as shown in FIG. 12, the cavity 54 may be configured to be constantly filled with a coolant 70. The cavity 54 includes a first flow path 541, a second flow path 542, and a third flow path 543. The first flow path 541 is provided between the first terminal 11 and the second terminal 12 in the first direction z. The second flow path 542 is provided between the first terminal 11 and the third terminal 13 in the first direction z. The third flow path 543 is provided between the second terminal 12 and the fourth terminal 14 in the first direction z. Note that the coolant 70 shown FIG. 12 needs to be an insulator. In the present disclosure, the coolant 70 may have any composition as long as the coolant 70 is an insulator.

As shown in FIGS. 1, 3, 4, and 6, the housing 50 has an inlet 55 and an outlet 56. The inlet 55 is provided in the third side surface 533 and is in communication with the cavity 54. The outlet 56 is provided in the fourth side surface 534 and is in communication with the cavity 54. The coolant 70 shown in FIG. 12 enters the housing 50 through the inlet 55 and flows into the cavity 54. Subsequently, the coolant 70 in the cavity 54 exits through the outlet 56. As shown in FIGS. 3 and 4, the inlet 55 and the outlet 56 are positioned opposite each other with respect to the first heat dissipation members 31 in the second direction x.

As shown in FIGS. 7-9, the first terminal 11 is positioned on one side in the first direction z from the first semiconductor elements 21. The first terminal 11 is a metal plate containing copper (Cu), for example. The first terminal 11 has a first base 111 and a first extension 112. The first base 111 is accommodated in the cavity 54 of the housing 50 and is in contact with the first flow path 541 and the second flow path 542. The first base 111 has a strip shape extending in the second direction x. The first extension 112 is electrically bonded to the first base 111 on one side in the second direction x. The first extension 112 is supported by the housing 50. The first extension 112 has a portion protruding outward from the second side surface 532 of the housing 50.

As shown in FIGS. 7-9, the second terminal 12 is positioned opposite the first semiconductor elements 21 with respect to the first terminal 11 in the first direction z. The second terminal 12 is a metal plate containing copper, for example. The second terminal 12 has a second base 121 and a second extension 122. The second base 121 is accommodated in the cavity 54 of the housing 50 and is in contact with the first flow path 541 and the third flow path 543. The second base 121 has a strip shape extending in the second direction x. The second base 121 has a second mounting surface 121A facing the same side as the top surface 51 of the housing 50 in the first direction z. The second extension 122 is electrically bonded to the second base 121 on one side in the second direction x. The second extension 122 is supported by the housing 50. The second extension 122 has a portion protruding outward from the second side surface 532 of the housing 50.

As shown in FIGS. 7-9, the third terminal 13 is positioned opposite the first terminal 11 with respect to the first semiconductor elements 21 in the first direction z. The third terminal 13 is a metal plate containing copper, for example. The third terminal 13 has a third base 131 and a third extension 132. The third base 131 is accommodated in the cavity 54 of the housing 50 and is in contact with the second flow path 542. The third base 131 has a strip shape extending in the second direction x. The third base 131 has a first mounting surface 131A facing the same side as the top surface 51 of the housing 50 in the first direction z. The third extension 132 is electrically bonded to the third base 131 on one side in the second direction x. The third extension 132 is supported by the housing 50. The third extension 132 has a portion protruding outward from the first side surface 531 of the housing 50.

As shown in FIGS. 7-9, the fourth terminal 14 is positioned opposite the second terminal 12 with respect to the second semiconductor elements 22 in the first direction z. The fourth terminal 14 is a metal plate containing copper, for example. The fourth terminal 14 has a fourth base 141 and a fourth extension 142. The fourth base 141 is accommodated in the cavity 54 of the housing 50 and is in contact with the third flow path 543. The fourth base 141 has a strip shape extending in the second direction x. The fourth extension 142 is electrically bonded to the fourth base 141 on one side in the second direction x. The fourth extension 142 is supported by the housing 50. The fourth extension 142 has a portion protruding outward from the first side surface 531 of the housing 50.

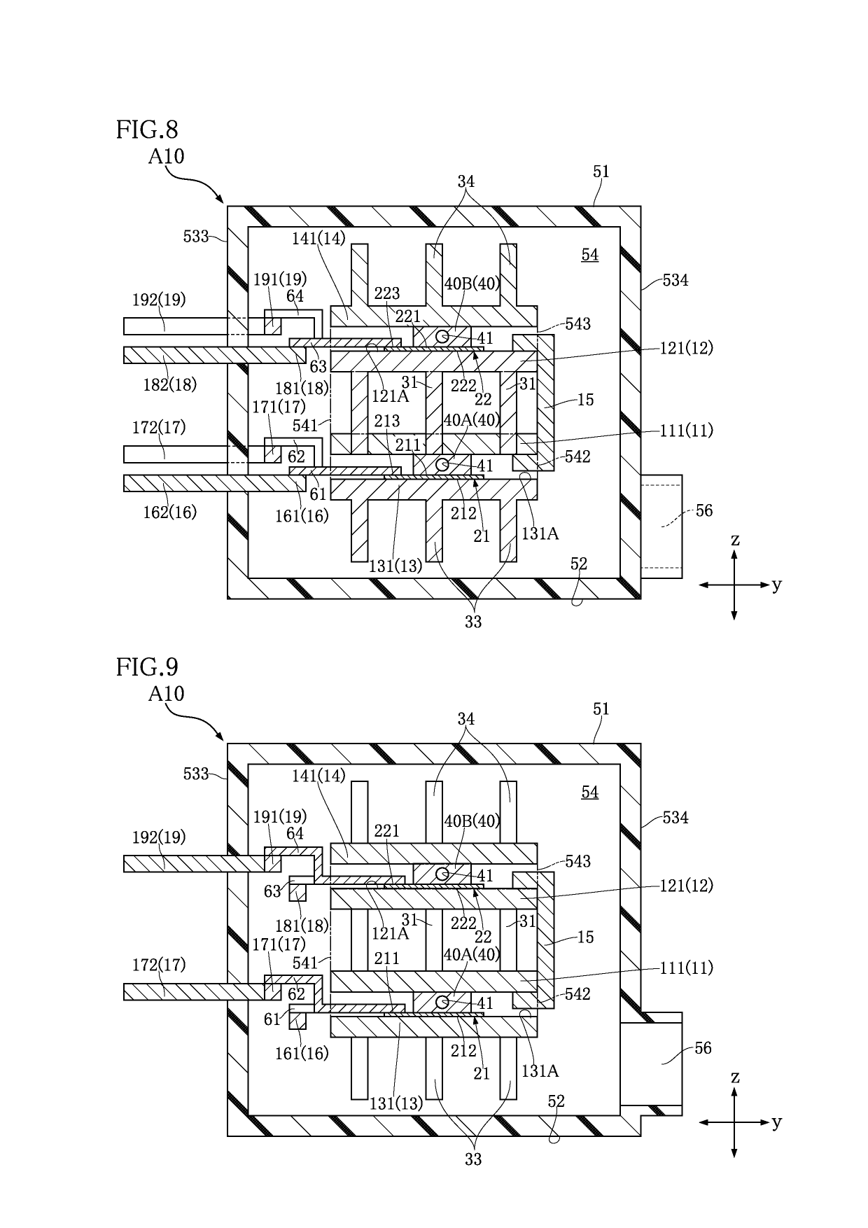

As shown in FIGS. 8 and 9, the conductive member 15 is electrically bonded to the first base 111 of the first terminal 11 and the second base 121 of the second terminal 12 on one side in the third direction y. As a result, the first terminal 11 and the second terminal 12 are electrically connected to each other. The conductive member 15 is a metal plate containing copper, for example. The conductive member 15 is accommodated in the cavity 54 of the housing 50.

As shown in FIGS. 7-9, the first semiconductor elements 21 are positioned opposite the second terminal 12 with respect to the first terminal 11 in the first direction z. In addition, the first semiconductor elements 21 are positioned between the first base 111 of the first terminal 11 and the third base 131 of the third terminal 13. The first semiconductor elements 21 are accommodated in the second flow path 542 of the cavity 54 of the housing 50. All of the first semiconductor elements 21 are identical. The first semiconductor elements 21 are MOSFETs (metal-oxide-semiconductor field-effect transistors), for example. Alternatively, the first semiconductor elements 21 may be field-effect transistors, including MISFETs (metal-insulator-semiconductor field-effect transistors), or bipolar transistors, including IGBTs (insulated gate bipolar transistors). In the description of the semiconductor device A10 below, the first semiconductor elements 21 are assumed to be n-channel, vertical MOSFETs. The first semiconductor elements 21 include a compound semiconductor substrate. The compound semiconductor substrate contains silicon carbide (SiC). The first semiconductor elements 21 are aligned along the second direction x.

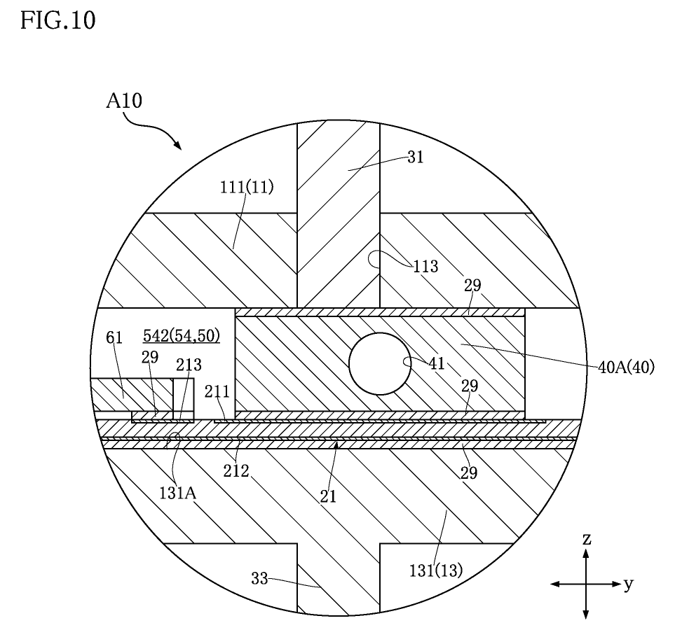

As shown in FIG. 10, each of the first semiconductor elements 21 includes a first electrode 211, a second electrode 212, and a first gate electrode 213.

As shown in FIG. 10, the first electrode 211 is positioned opposite the side that faces the first mounting surface 131A of the third base 131 of the third terminal 13 in the first direction z. The first electrode 211 is electrically connected to the first terminal 11 and the second terminal 12. The first electrode 211 carries the current corresponding to the power after conversion by the first semiconductor element 21. In other words, the first electrode 211 corresponds to the source of the first semiconductor element 21.

As shown in FIG. 10, the second electrode 212 faces the first mounting surface 131A of the third base 131 of the third terminal 13. The second electrode 212 is electrically bonded to the first mounting surface 131A via a bonding layer 29. The bonding layer 29 is solder. Alternatively, the bonding layer 29 may be a sintered metal containing silver (Ag), for example. The second electrode 212 carries the current corresponding to the power before conversion by the first semiconductor elements 21. In other words, the second electrode 212 corresponds to the drain of the first semiconductor element 21.

As shown in FIG. 10, the first gate electrode 213 is positioned on the same side as the first electrode 211 in the first direction z. The first gate electrode 213 receives a gate voltage for driving the first semiconductor element 21. As shown in FIG. 5, the first gate electrode 213 has a smaller area than the first electrode 211 as viewed in the first direction z.

As shown in FIGS. 7-9, the second semiconductor elements 22 are positioned opposite the first terminal 11 with respect to the second terminal 12 in the first direction z. In addition, the second semiconductor elements 22 are positioned between the second base 121 of the second terminal 12 and the fourth base 141 of the fourth terminal 14 in the first direction z. The second semiconductor elements 22 are accommodated in the third flow path 543 of the cavity 54 of the housing 50. As viewed in the first direction z, the second semiconductor elements 22 overlap with the respective first semiconductor elements 21. The second semiconductor elements 22 are identical to the first semiconductor elements 21. Thus, the second semiconductor elements 22 are n-channel, vertical MOSFETs. The second semiconductor elements 22 are aligned along the second direction x.

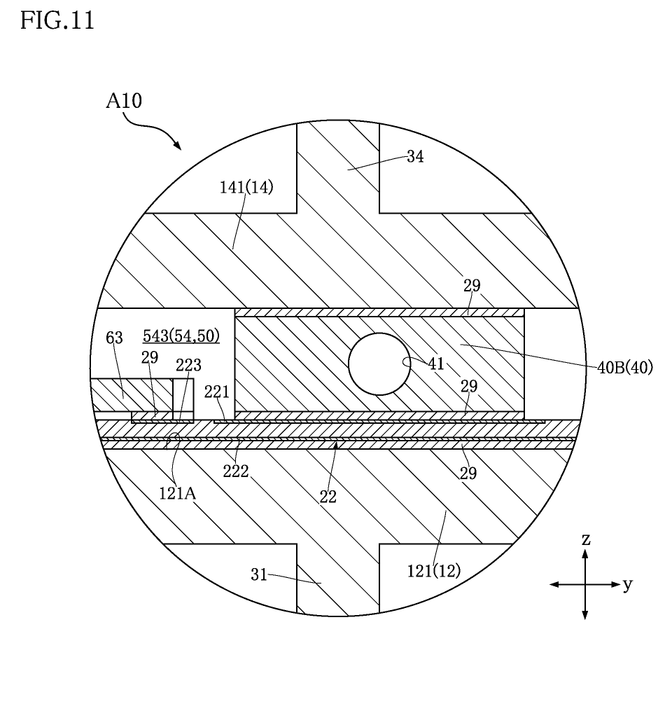

As shown in FIG. 11, each of the second semiconductor elements 22 has a third electrode 221, a fourth electrode 222, and a second gate electrode 223.

As shown in FIG. 11, the third electrode 221 is positioned opposite the side that faces the second mounting surface 121A of the second base 121 of the second terminal 12 in the first direction z. The third electrode 221 is electrically connected to the fourth terminal 14. The third electrode 221 carries the current corresponding to the power after conversion by the second semiconductor element 22. In other words, the third electrode 221 corresponds to the source of the second semiconductor element 22.

As shown in FIG. 11, the fourth electrode 222 faces the second mounting surface 121A of the second base 121 of the second terminal 12. The fourth electrode 222 is electrically bonded to the second mounting surface 121A via a bonding layer 29. The fourth electrode 222 carries the current corresponding to the power before conversion by the second semiconductor element 22. In other words, the fourth electrode 222 corresponds to the drain of the second semiconductor element 22.

As shown in FIG. 11, the second gate electrode 223 is positioned on the same side as the third electrode 221 in the first direction z. The second gate electrode 223 receives a gate voltage for driving the second semiconductor element 22. As shown in FIG. 3, the second gate electrode 223 has a smaller area than the third electrode 221 as viewed in the first direction z.

As shown in FIGS. 7-9, the spacers 40 include the first spacers 40A and the second spacers 40B. The spacers 40 are metal blocks that contain copper, for example. As shown in FIG. 10, each of the first spacers 40A is electrically bonded to the first electrode 211 of one of the first semiconductor elements 21 and the first base 111 of the first terminal 11 via a bonding layer 29. As a result, the first electrodes 211 of the first semiconductor elements 21 are electrically connected to the first terminal 11. The first spacers 40A are accommodated in the second flow path 542 of the cavity 54 of the housing 50. The dimension of each first spacer 40A in the first direction z is larger than the dimension of each first semiconductor element 21 in the first direction z.

As shown in FIG. 11, each of the second spacers 40B is electrically bonded to the third electrode 221 of one of the second semiconductor elements 22 and the fourth base 141 of the fourth terminal 14 via a bonding layer 29. As a result, the third electrodes 221 of the second semiconductor elements 22 are electrically connected to the fourth terminal 14. The second spacers 40B are accommodated in the third flow path 543 of the cavity 54 of the housing 50. The dimension of each second spacer 40B in the first direction z is larger than the dimension of each second semiconductor element 22 in the first direction z.

As shown in FIGS. 3, 4, 10, and 11, each of the spacers 40 is provided with a through portion 41 that penetrates the spacer 40 in the second direction x. The through portions 41 of the first spacers 40A are connected to the second flow path 542 of the cavity 54 of the housing 50. The through portions 41 of the second spacers 40B are connected to the third flow path 543 of the cavity 54.

As shown in FIGS. 4 and 5, the first signal terminal 16 is positioned on one side in the third direction y from the first terminal 11 and the third terminal 13. The first signal terminal 16 is supported by the housing 50. The first signal terminal 16 is electrically connected to the first gate electrode 213 of each first semiconductor element 21. The first signal terminal 16 receives a gate voltage for driving the first semiconductor elements 21. The first signal terminal 16 is a metal lead containing copper, for example. The first signal terminal 16 has an inner portion 161 and an outer portion 162. The inner portion 161 is accommodated in the housing 50. The inner portion 161 has a portion accommodated in the cavity 54 of the housing 50. The inner portion 161 has a portion extending in the second direction x. The outer portion 162 is connected to the inner portion 161. As shown in FIG. 8, the outer portion 162 protrudes outward from the third side surface 533 of the housing 50.

Each of the first leads 61 is electrically connected to the first gate electrode 213 of a first semiconductor element 21 and the first signal terminal 16. As shown in FIG. 5, the first leads 61 extend in the third direction y. As shown in FIG. 8, each of the first leads 61 has a portion accommodated in the second flow path 542 of the cavity 54 of the housing 50. Each of the first leads 61 is a metal lead containing copper, for example. One end of each first lead 61 in the third direction y is electrically bonded to the first gate electrode 213 of a first semiconductor element 21 via a bonding layer 29. The other end of each first lead 61 in the third direction y is electrically bonded to the inner portion 161 of the first signal terminal 16.

As shown in FIGS. 4 and 5, the second signal terminal 17 is positioned on the same side as the first signal terminal 16 with respect to the first terminal 11 and the third terminal 13 in the third direction y. The second signal terminal 17 is supported by the housing 50. The second signal terminal 17 is electrically connected to the first electrode 211 of each first semiconductor element 21. The second signal terminal 17 receives a voltage that is equal to the voltage applied to the first electrode 211 of each first semiconductor element 21. The second signal terminal 17 is a metal lead containing copper, for example. The second signal terminal 17 has an inner portion 171 and an outer portion 172. The inner portion 171 is accommodated in the housing 50. The inner portion 171 has a portion accommodated in the cavity 54 of the housing 50. The inner portion 171 has a portion extending in the second direction x. As shown in FIGS. 8 and 9, the inner portion 171 is positioned closer to the top surface 51 of the housing 50 than is the inner portion 161 of the first signal terminal 16. The outer portion 172 is connected to the inner portion 171. As shown in FIG. 9, the outer portion 172 protrudes outward from the third side surface 533 of the housing 50.

Each of the second leads 62 is electrically connected to the first electrode 211 of a first semiconductor element 21 and the second signal terminal 17. As shown in FIG. 5, the second leads 62 extend in the third direction y as viewed in the first direction z. As shown in FIG. 9, the second leads 62 extend across the inner portion 161 of the first signal terminal 16. Each of the second leads 62 has a portion accommodated in the second flow path 542 of the cavity 54 of the housing 50. Each of the second leads 62 is a metal lead containing copper, for example. One end of each second lead 62 in the third direction y is electrically bonded to the first electrode 211 of a first semiconductor element 21. The other end of each second lead 62 in the third direction y is electrically bonded to the inner portion 171 of the second signal terminal 17.

As shown in FIGS. 2 and 3, the third signal terminal 18 is positioned on one side in the third direction y from the second terminal 12 and the fourth terminal 14. As viewed in the first direction z, the third signal terminal 18 overlaps with the first signal terminal 16. The third signal terminal 18 is supported by the housing 50. The third signal terminal 18 is electrically connected to the second gate electrode 223 of each second semiconductor element 22. The third signal terminal 18 receives a gate voltage for driving the second semiconductor elements 22. The third signal terminal 18 is a metal lead containing copper, for example. The third signal terminal 18 has an inner portion 181 and an outer portion 182. The inner portion 181 is accommodated in the housing 50. Further, the inner portion 181 has a portion accommodated in the cavity 54 of the housing 50. The inner portion 181 has a portion extending in the second direction x. The outer portion 182 is connected to the inner portion 181. As shown in FIG. 8, the outer portion 182 protrudes outward from the third side surface 533 of the housing 50.

Each of the third leads 63 is electrically connected to the second gate electrode 223 of a second semiconductor element 22 and the third signal terminal 18. As shown in FIG. 3, the third leads 63 extend in the third direction y. As shown in FIG. 8, each of the third leads 63 has a portion accommodated in the third flow path 543 of the cavity 54 of the housing 50. Each of the third leads 63 is a metal lead containing copper, for example. One end of each third lead 63 in the third direction y is electrically bonded to the second gate electrode 223 of a second semiconductor element 22 via a bonding layer 29. The other end of each third lead 63 in the third direction y is electrically bonded to the inner portion 181 of the third signal terminal 18.

As shown in FIGS. 2 and 3, the fourth signal terminal 19 is positioned on the same side as the third signal terminal 18 with respect to the second terminal 12 and the fourth terminal 14 in the third direction y. As viewed in the first direction z, the fourth signal terminal 19 overlaps with the second signal terminal 17. The fourth signal terminal 19 is supported by the housing 50. The fourth signal terminal 19 is electrically connected to the third electrode 221 of each second semiconductor element 22. The fourth signal terminal 19 receives a voltage that is equal to the voltage applied to the third electrode 221 of each second semiconductor element 22. The fourth signal terminal 19 is a metal lead containing copper, for example. The fourth signal terminal 19 has an inner portion 191 and an outer portion 192. The inner portion 191 is accommodated in the housing 50. Further, the inner portion 191 has a portion accommodated in the cavity 54 of the housing 50. The inner portion 191 has a portion extending in the second direction x. As shown in FIGS. 8 and 9, the inner portion 191 is positioned closer to the top surface 51 of the housing 50 than is the inner portion 181 of the third signal terminal 18. The outer portion 192 is connected to the inner portion 191. As shown in FIG. 9, the outer portion 192 protrudes outward from the third side surface 533 of the housing 50.

Each of the fourth leads 64 is electrically connected to the third electrode 221 of a second semiconductor element 22 and the fourth signal terminal 19. As shown in FIG. 3, the fourth leads 64 extend in the third direction y as viewed in the first direction z. As shown in FIG. 9, the fourth leads 64 extend across the inner portion 181 of the third signal terminal 18. Each of the fourth leads 64 has a portion accommodated in the third flow path 543 of the cavity 54 of the housing 50. Each of the fourth leads 64 is a metal lead containing copper, for example. One end of each fourth lead 64 in the third direction y is electrically bonded to the third electrode 221 of a second semiconductor element 22. The other end of each fourth lead 64 in the third direction y is electrically bonded to the inner portion 191 of the fourth signal terminal 19.

As shown in FIGS. 7-9, the first heat dissipation members 31 are connected to the first base 111 of the first terminal 11 and the second base 121 of the second terminal 12. The first heat dissipation members 31 are accommodated in the first flow path 541 of the cavity 54 of the housing 50. The first heat dissipation members 31 are rod members containing copper, for example. The first heat dissipation members 31 extend in the first direction z. In the semiconductor device A10, one end of each first heat dissipation member 31 in the first direction z is electrically bonded to the second base 121 by laser welding, for example. The other end of each first heat dissipation member 31 in the first direction z is electrically bonded to the first base 111 by laser welding, for example. As shown in FIG. 10, at least one of the first base 111 and the second base 121 is provided with a plurality of support portions 113 that penetrate therethrough in the first direction z. Each of the first heat dissipation members 31 has a portion accommodated in one of the support portions 113.

As shown in FIGS. 7 and 8, the third heat dissipation members 33 are connected to the third base 131 of the third terminal 13. The third heat dissipation members 33 are positioned opposite the first semiconductor elements 21 with respect to the third terminal 13 in the first direction z. The third heat dissipation members 33 are accommodated in the cavity 54 of the housing 50. The third heat dissipation members 33 are rod members containing copper, for example. The third heat dissipation members 33 extend in the first direction z. In the semiconductor device A10, one end of each third heat dissipation member 33 in the first direction z is electrically bonded to the third base 131 by laser welding, for example.

As shown in FIGS. 7 and 8, the fourth heat dissipation members 34 are connected to the fourth base 141 of the fourth terminal 14. The fourth heat dissipation members 34 are positioned opposite the second semiconductor elements 22 with respect to the fourth terminal 14 in the first direction z. The fourth heat dissipation members 34 are accommodated in the cavity 54 of the housing 50. The fourth heat dissipation members 34 are rod members containing copper, for example. The fourth heat dissipation members 34 extend in the first direction z. In the semiconductor device A10, one end of each fourth heat dissipation member 34 in the first direction z is electrically bonded to the fourth base 141 by laser welding, for example.

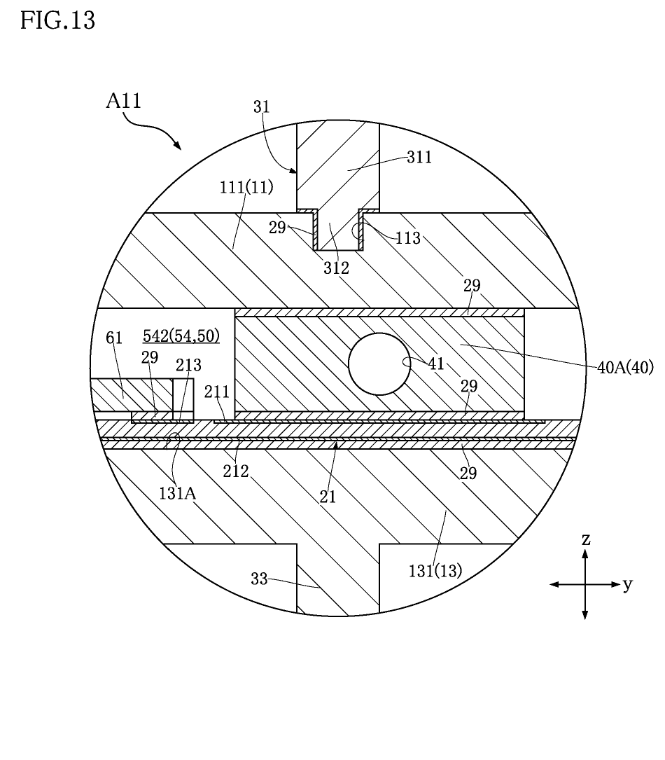

The following describes a semiconductor device A11 according to a first variation of the first embodiment of the present disclosure, with reference to FIG. 13. Note that FIG. 13 corresponds to FIG. 10.

As shown in FIG. 13, the semiconductor device A11 is different from the semiconductor device A10 in the configurations of the first terminal 11 and the first heat dissipation members 31. The support portions 113 are recessed from the first base 111 on one side in the first direction z. Each of the first heat dissipation members 31 has a first main portion 311 and a first engagement portion 312. The first main portion 311 is connected to the second base 121 of the second terminal 12. The first engagement portion 312 is positioned opposite the second base 121 with respect to the first main portion 311 in the first direction z. The first engagement portion 312 protrudes from the first main portion 311 in the first direction z. The first engagement portion 312 is inserted in one of the support portions 113. The first engagement portion 312 is electrically bonded to the first base 111 via a bonding layer 29.

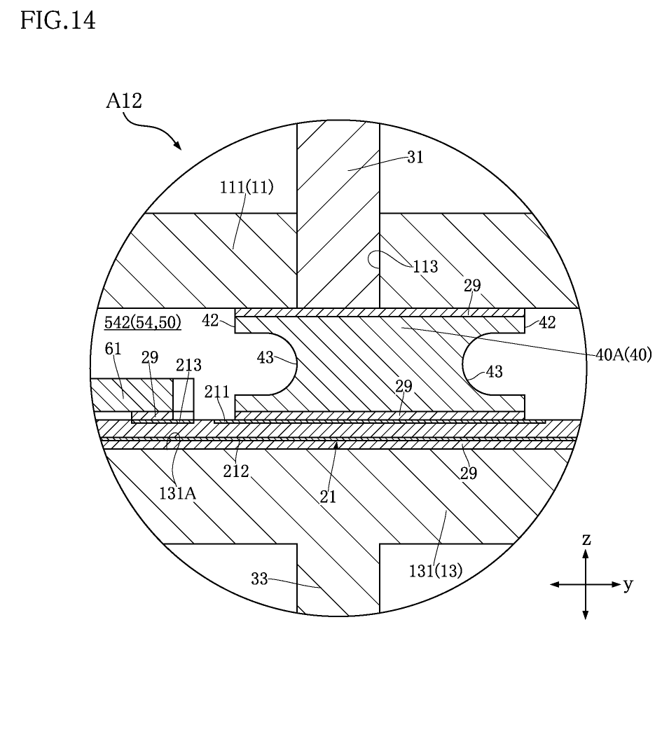

The following describes a semiconductor device A12 according to a second variation of the first embodiment of the present disclosure, with reference to FIG. 14. Note that FIG. 14 corresponds to FIG. 10.

As shown in FIG. 14, the semiconductor device A12 is different from the semiconductor device A10 in the configuration of the spacers 40. Each of the spacers 40 has a plurality of peripheral surfaces 42 that face in a direction perpendicular to the first direction z. In the semiconductor device A12, each of the spacers 40 is provided with two grooves 43 recessed from two regions of the peripheral surfaces 42. The two regions are spaced apart from each other in the third direction y. The two grooves 43 extend in the second direction x. Each of the two grooves 43 is defined by a curved surface recessed in the third direction y.

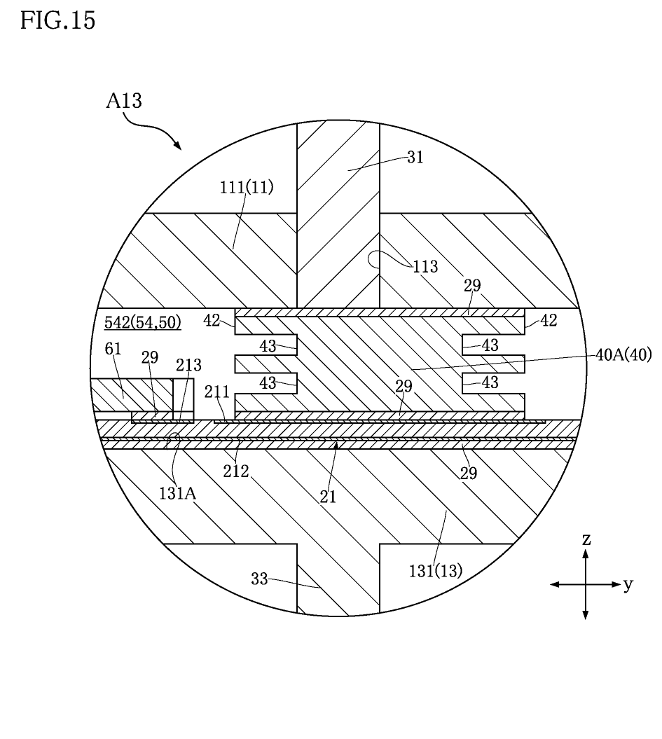

The following describes a semiconductor device A13 according to a third variation of the first embodiment of the present disclosure, with reference to FIG. 15. Note that FIG. 15 corresponds to FIG. 10.

As shown in FIG. 15, the semiconductor device A13 is different from the semiconductor device A10 in the configuration of the spacers 40. Each of the spacers 40 has a plurality of peripheral surfaces 42 that face in a direction perpendicular to the first direction z. In the semiconductor device A13, each of the spacers 40 is provided with a plurality of grooves 43 recessed from two regions of the peripheral surfaces 42. The two regions are spaced apart from each other in the third direction y. The grooves 43 extend in the second direction x. The grooves 43 in each of the two regions are aligned in the first direction z.

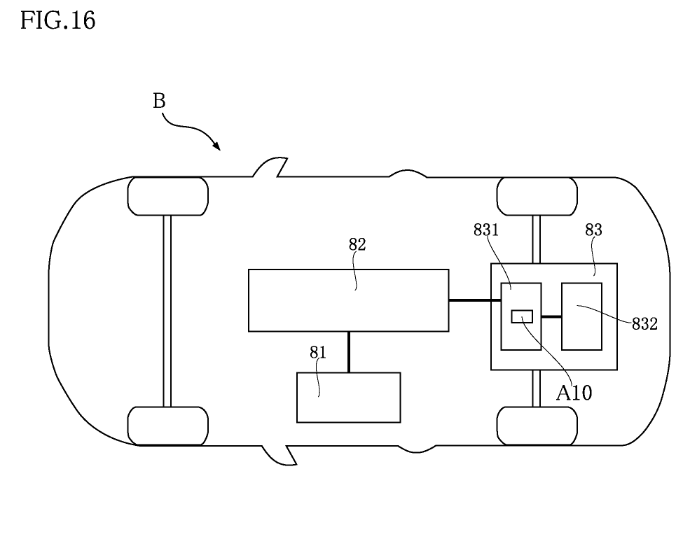

The following describes a vehicle B equipped with the semiconductor device A10 with reference to FIG. 16. In one example, the vehicle B is an electric vehicle (EV).

As shown in FIG. 16, the vehicle B includes an on-board charger 81, a storage battery 82, and a drive system 83. The on-board charger 81 wirelessly receives power from an outdoor power supply facility (not shown). Alternatively, the on-board charger 81 may receive power from the power supply facility via a wired connection. The on-board charger 81 includes a step-up DC-DC converter. The converter increases the voltage of the power supplied to the on-board charger 81 and supplies the resulting power to the storage battery 82. The voltage is increased to 600 V, for example.

The drive system 83 drives the vehicle B. The drive system 83 has an inverter 831 and a drive source 832. The semiconductor device A10 forms a part of the inverter 831. The power stored on the storage battery 82 is supplied to the inverter 831. The storage battery 82 supplies DC power to the inverter 831. Unlike the power system shown in FIG. 16, an additional step-up DC-DC converter may be provided between the storage battery 82 and the inverter 831. The inverter 831 converts the DC power to AC power. The inverter 831, including the semiconductor device A10, is electrically connected to the drive source 832. The drive source 832 includes an AC motor and a transmission. When the AC power from the inverter 831 is supplied to the drive source 832, the AC motor rotates and transmits its rotation to the transmission. The transmission reduces the rotational speed transmitted from the AC motor as needed, and rotates the axle of the vehicle B. This causes the vehicle B to drive. While the vehicle B is being driven, the rotational speed of the AC motor needs to be adjusted based on relevant information, such as the position of the accelerator pedal. The semiconductor device A10 in the inverter 831 is used to output the AC power at a frequency appropriately adjusted to correspond to the required rotational speed of the AC motor.

The following describes advantages of the semiconductor device A10.

The semiconductor device A10 includes a first terminal 11, a second terminal 12, first semiconductor elements 21, and first heat dissipation members 31. The first semiconductor elements 21 are positioned opposite the second terminal 12 with respect to the first terminal 11 in the first direction z, and are electrically connected to the first terminal 11. The first heat dissipation members 31 are connected to the first terminal 11. In the first direction z, a first flow path 541 is provided between the first terminal 11 and the second terminal 12. The first heat dissipation members 31 are accommodated in the first flow path 541. With this configuration, as shown in FIG. 12, when the coolant 70 flows into the cavity 54 of the housing 50, the coolant 70 flows downward into the first flow path 541. As a result, the coolant 70 makes direct contact with the first heat dissipation members 31, thereby improving the cooling efficiency of the semiconductor device A10 as compared to conventional techniques. Thus, with this configuration, it is possible to further improve the cooling efficiency of the semiconductor device A10.

The first terminal 11 and the second terminal 12 are in contact with the first flow path 541. With this configuration, the coolant 70 also makes direct contact with the first terminal 11 and the second terminal 12, thereby further improving the cooling efficiency of the semiconductor device A10.

The first heat dissipation members 31 are connected to the second terminal 12. The second semiconductor elements 22 are electrically bonded to the second terminal 12. With this configuration, the heat conducted from the second semiconductor elements 22 to the second terminal 12 can be dissipated to the coolant 70 via the first heat dissipation members 31.

The semiconductor device A10 further includes a third terminal 13 positioned opposite the first terminal 11 with respect to the first semiconductor elements 21. The first semiconductor elements 21 are electrically connected to the third terminal 13. In the first direction z, a second flow path 542 is provided between the first terminal 11 and the third terminal 13. The first semiconductor elements 21 are accommodated in the second flow path 542. With this configuration, as shown in FIG. 12, when the coolant 70 flows into the cavity 54 of the housing 50, the coolant 70 flows downward into the second flow path 542. With this configuration, the coolant 70 makes direct contact with the first semiconductor elements 21, thereby further improving the cooling efficiency of the semiconductor device A10.

The semiconductor device A10 further includes first spacers 40A electrically bonded to the first terminal 11 and the first semiconductor elements 21. The first spacers 40A are accommodated in the second flow path 542. The dimension of each first spacer 40A in the first direction z is larger than the dimension of each first semiconductor element 21 in the first direction z. With this configuration, the coolant 70 also makes direct contact with the first spacers 40A, thereby further improving the cooling efficiency of the semiconductor device A10. Further, the first spacers 40A can more appropriately ensure the cross-sectional area of the second flow path 542 for downward flow.

Each of the first spacers 40A is provided with a through portion 41 that penetrates the first spacer 40A in a direction perpendicular to the first direction z. This configuration increases the surface area of each first spacer 40A and allows the coolant 70 to flow downward into the through portions 41. As a result, the cooling efficiency of the semiconductor device A10 improves more effectively.

The semiconductor device A10 further includes a housing 50 that supports the first terminal 11, the second terminal 12, and the third terminal 13. The housing 50 is provided with an inlet 55 and an outlet 56. The inlet 55 and the outlet 56 are positioned opposite each other with respect to the first heat dissipation members 31 in a direction perpendicular to the first direction z. This configuration allows the coolant 70 to flow downward such that the coolant 70 easily makes direct contact with the first heat dissipation members 31.

### Second Embodiment

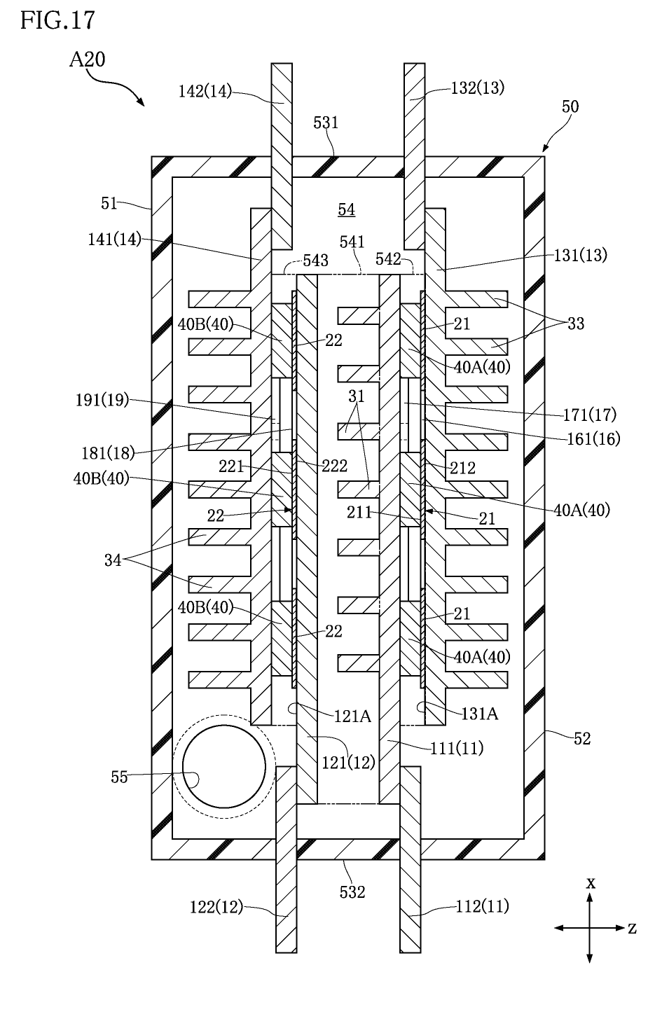

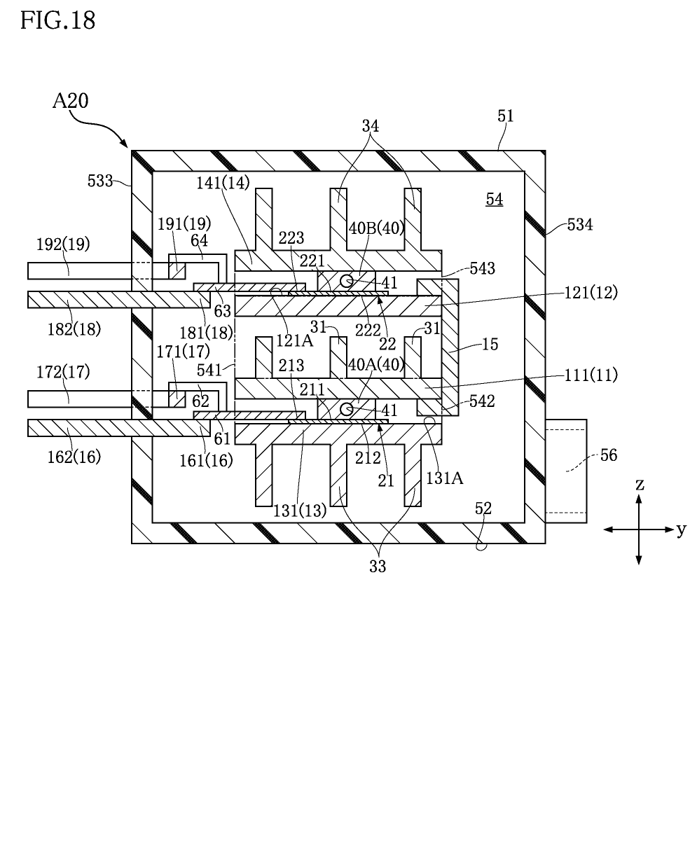

The following describes a semiconductor device A20 according to a second embodiment of the present disclosure, with reference to FIGS. 17 and 18. In these figures, elements that are identical or similar to those of the semiconductor device A10 are indicated by the same reference numerals, and overlapping descriptions are omitted. Note that FIG. 17 corresponds to FIG. 7 that shows the semiconductor device A10. FIG. 18 corresponds to FIG. 8 that shows the semiconductor device A10.

The semiconductor device A20 is different from the semiconductor device A10 in the configuration of the first heat dissipation members 31.

As shown in FIGS. 17 and 18, the first heat dissipation members 31 are spaced apart from the second terminal 12. As a result, there is a gap between the first heat dissipation members 31 and the second base 121 of the second terminal 12 in the first direction z. The gap corresponds to a portion of the first flow path 541 of the cavity 54 of the housing 50.

The following describes advantages of the semiconductor device A20.

The semiconductor device A20 includes a first terminal 11, a second terminal 12, first semiconductor elements 21, and first heat dissipation members 31. The first semiconductor elements 21 are positioned opposite the second terminal 12 with respect to the first terminal 11 in the first direction z, and are electrically connected to the first terminal 11. The first heat dissipation members 31 are connected to the first terminal 11. In the first direction z, a first flow path 541 is provided between the first terminal 11 and the second terminal 12. The first heat dissipation members 31 are accommodated in the first flow path 541. Thus, with this configuration, it is possible to further improve the cooling efficiency of the semiconductor device A20. Further, the semiconductor device A20 has configurations similar to the semiconductor device A10, thereby achieving the same advantages as the semiconductor device A10.

### Third Embodiment

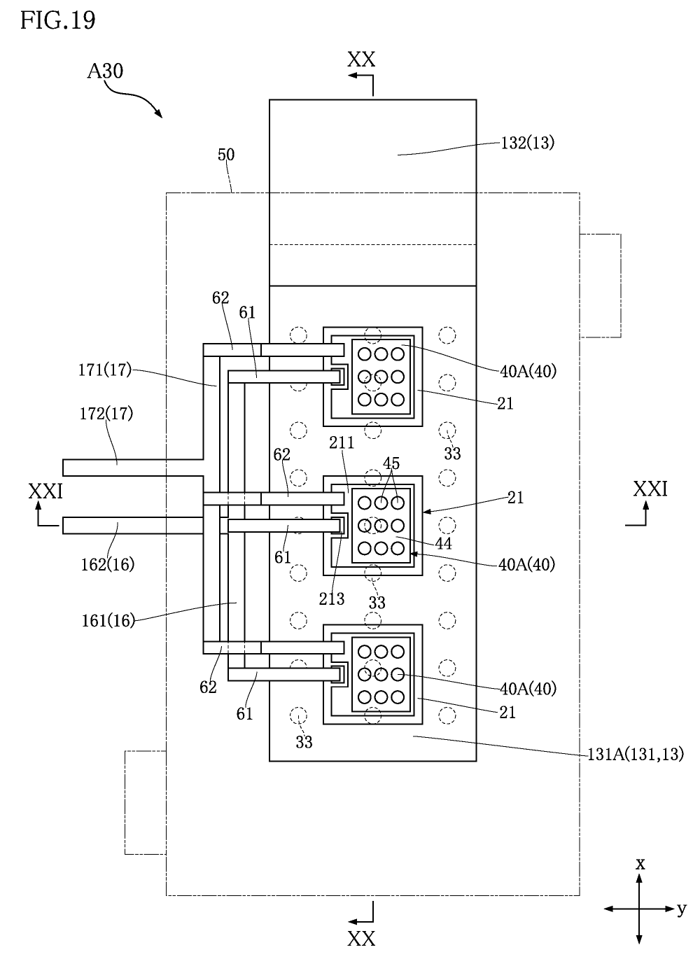

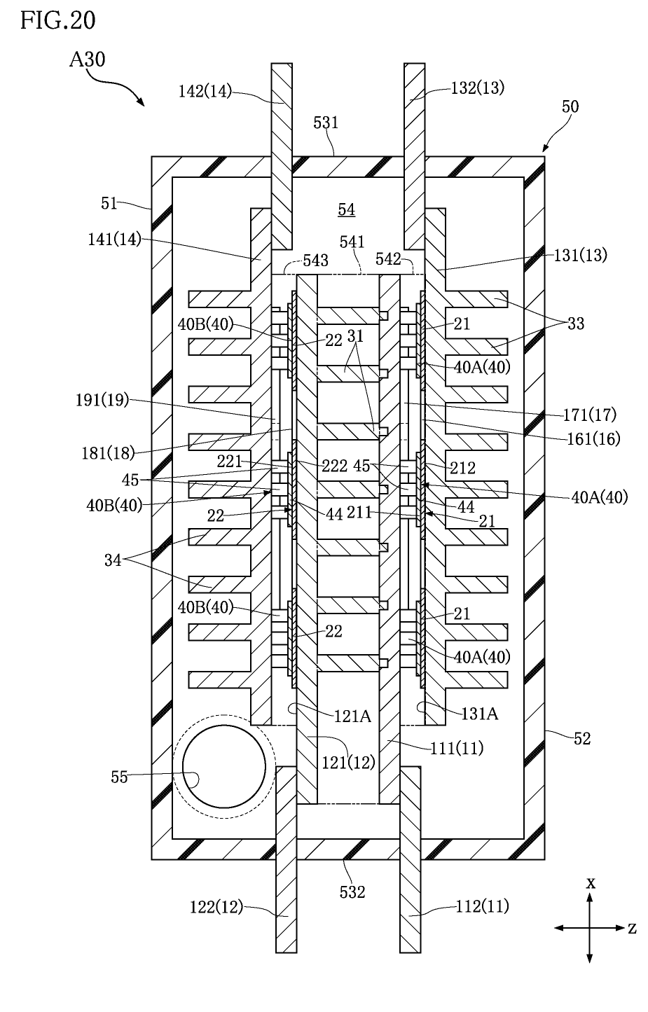

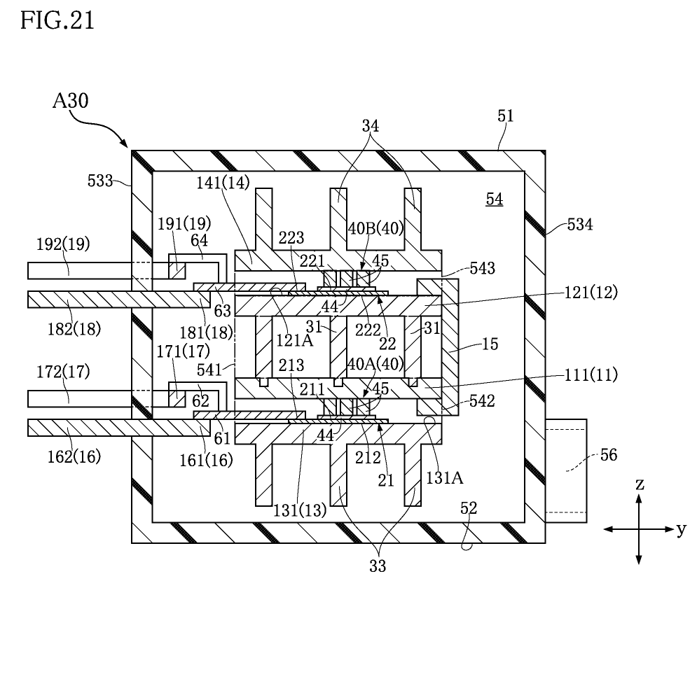

The following describes a semiconductor device A30 according to a third embodiment of the present disclosure, with reference to FIGS. 19-22. In these figures, elements that are identical or similar to those of the semiconductor device A10 are indicated by the same reference numerals, and overlapping descriptions are omitted. Note that FIG. 19 corresponds to FIG. 5 that shows the semiconductor device A10.

The semiconductor device A30 is different from the semiconductor device A10 in the configuration of the spacers 40.

As shown in FIGS. 19-21, each of the spacers 40 has a first pedestal 44 and a plurality of pillars 45. The pillars 45 are positioned opposite the first semiconductor elements 21 or the second semiconductor elements 22 with respect to the first pedestal 44 in the first direction z. The pillars 45 are spaced apart from each other in a direction perpendicular to the first direction z. The pillars 45 are electrically connected to the first pedestal 44.

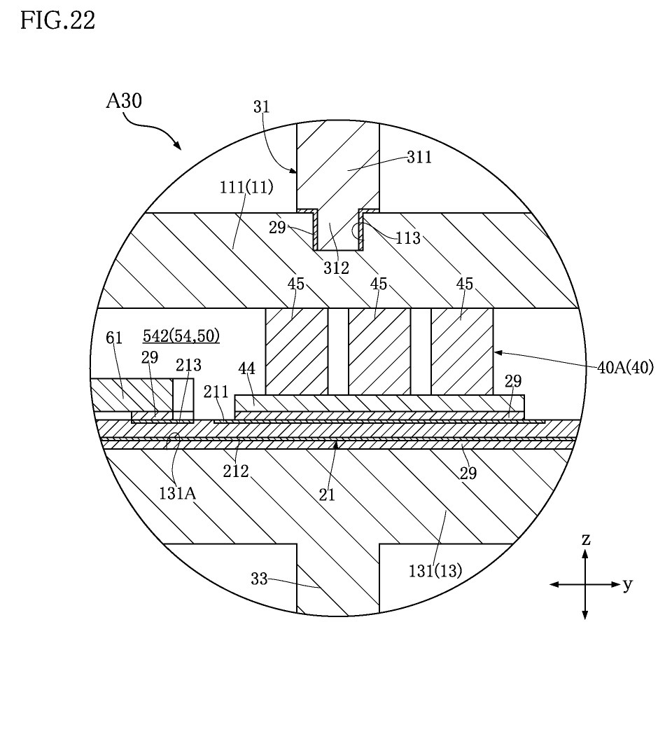

As shown in FIG. 22, the first pedestal 44 of each first spacer 40A is electrically bonded to the first electrode 211 of one of the first semiconductor elements 21 via a bonding layer 29. The pillars 45 are electrically bonded to the first base 111 of the first terminal 11 by laser welding, for example. Thus, the pillars 45 of the first spacers 40A are electrically connected to the first terminal 11.

As with the first spacers 40A, the first pedestal 44 of each second spacer 40B is electrically bonded to the third electrode 221 of one of the second semiconductor elements 22 via a bonding layer 29. The pillars 45 are electrically bonded to the fourth base 141 of the fourth terminal 14 by laser welding, for example. Thus, the pillars 45 of the second spacers 40B are electrically connected to the fourth terminal 14.

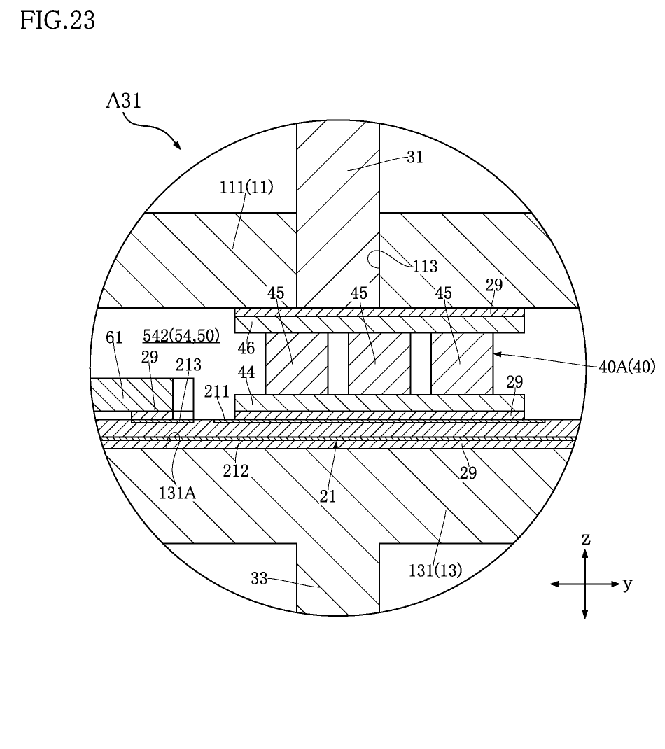

The following describes a semiconductor device A31 according to a variation of the third embodiment of the present disclosure, with reference to FIG. 23. Note that FIG. 23 corresponds to FIG. 22.

As shown in FIG. 23, the semiconductor device A31 is different from the semiconductor device A30 in the configuration of the first spacers 40A. Each of the first spacers 40A has a first pedestal 44, a plurality of pillars 45, and a second pedestal 46. The second pedestal 46 is positioned opposite the first pedestal 44 with respect to the pillars 45 in the first direction z. The pillars 45 are electrically connected to the second pedestal 46. The second pedestal 46 is electrically bonded to the first base 111 of the first terminal 11 via a bonding layer 29.

The following describes advantages of the semiconductor device A30.

The semiconductor device A30 includes a first terminal 11, a second terminal 12, first semiconductor elements 21, and first heat dissipation members 31. The first semiconductor elements 21 are positioned opposite the second terminal 12 with respect to the first terminal 11 in the first direction z, and are electrically connected to the first terminal 11. The first heat dissipation members 31 are connected to the first terminal 11. In the first direction z, a first flow path 541 is provided between the first terminal 11 and the second terminal 12. The first heat dissipation members 31 are accommodated in the first flow path 541. Thus, with this configuration, it is possible to further improve the cooling efficiency of the semiconductor device A30. Further, the semiconductor device A30 has configurations similar to the semiconductor device A10, thereby achieving the same advantages as the semiconductor device A10.

In the semiconductor device A30, each of the first spacers 40A has a first pedestal 44 electrically bonded to a first semiconductor element 21 and a plurality of pillars 45 positioned opposite the first semiconductor element 21 with respect to the first pedestal 44 in the first direction z. The pillars 45 are spaced apart from each other in a direction perpendicular to the first direction z. The pillars 45 are electrically connected to the first pedestal 44, and are in electrical conduction with the first terminal 11. This configuration increases the surface area of each first spacer 40A. As a result, the cooling efficiency of the semiconductor device A30 improves more effectively.

### Fourth Embodiment

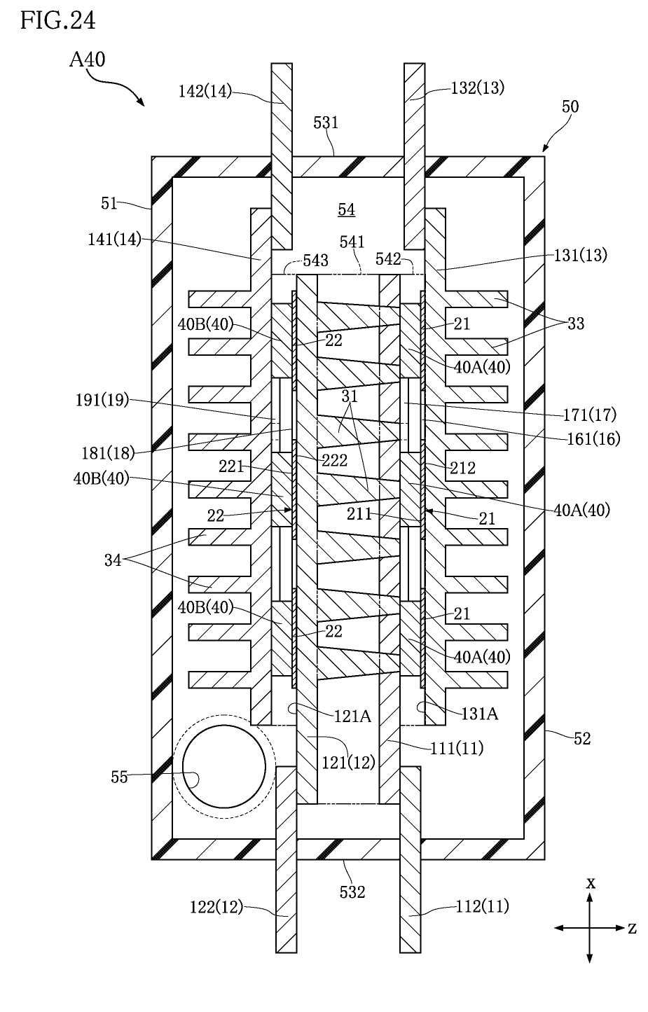

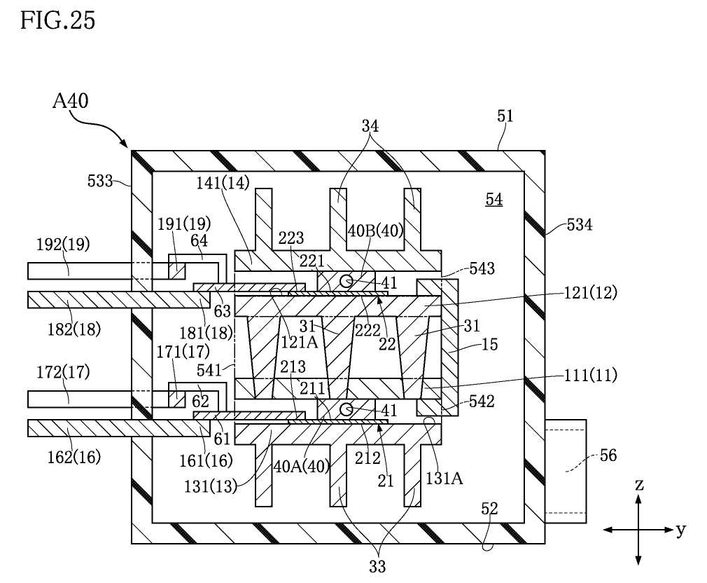

The following describes a semiconductor device A40 according to a fourth embodiment of the present disclosure, with reference to FIGS. 24 and 25. In these figures, elements that are identical or similar to those of the semiconductor device A10 are indicated by the same reference numerals, and overlapping descriptions are omitted. Note that FIG. 24 corresponds to FIG. 7 that shows the semiconductor device A10. FIG. 25 corresponds to FIG. 8 that shows the semiconductor device A10.

The semiconductor device A40 is different from the semiconductor device A10 in the configuration of the first heat dissipation members 31.

As shown in FIGS. 24 and 25, each first heat dissipation member 31 has a cross section perpendicular to the first direction z, and the area of the cross section increases from the first base 111 of the first terminal 11 toward the second base 121 of the second terminal 12.

The following describes advantages of the semiconductor device A40.

The semiconductor device A40 includes a first terminal 11, a second terminal 12, first semiconductor elements 21, and first heat dissipation members 31. The first semiconductor elements 21 are positioned opposite the second terminal 12 with respect to the first terminal 11 in the first direction z, and are electrically connected to the first terminal 11. The first heat dissipation members 31 are connected to the first terminal 11. In the first direction z, a first flow path 541 is provided between the first terminal 11 and the second terminal 12. The first heat dissipation members 31 are accommodated in the first flow path 541. Thus, with this configuration, it is possible to further improve the cooling efficiency of the semiconductor device A40. Further, the semiconductor device A40 has configurations similar to the semiconductor device A10, thereby achieving the same advantages as the semiconductor device A10.

In the semiconductor device A40, each first heat dissipation member 31 has a cross section perpendicular to the first direction z, and the area of the cross section increases from the first terminal 11 toward the second terminal 12. This configuration increases the surface area of each first heat dissipation member 31. In addition, the heat conducted from the first semiconductor elements 21 to the first heat dissipation members 31 is easily dissipated at the first heat dissipation members 31. As a result, the cooling efficiency of the semiconductor device A40 improves more effectively.

### Fifth Embodiment

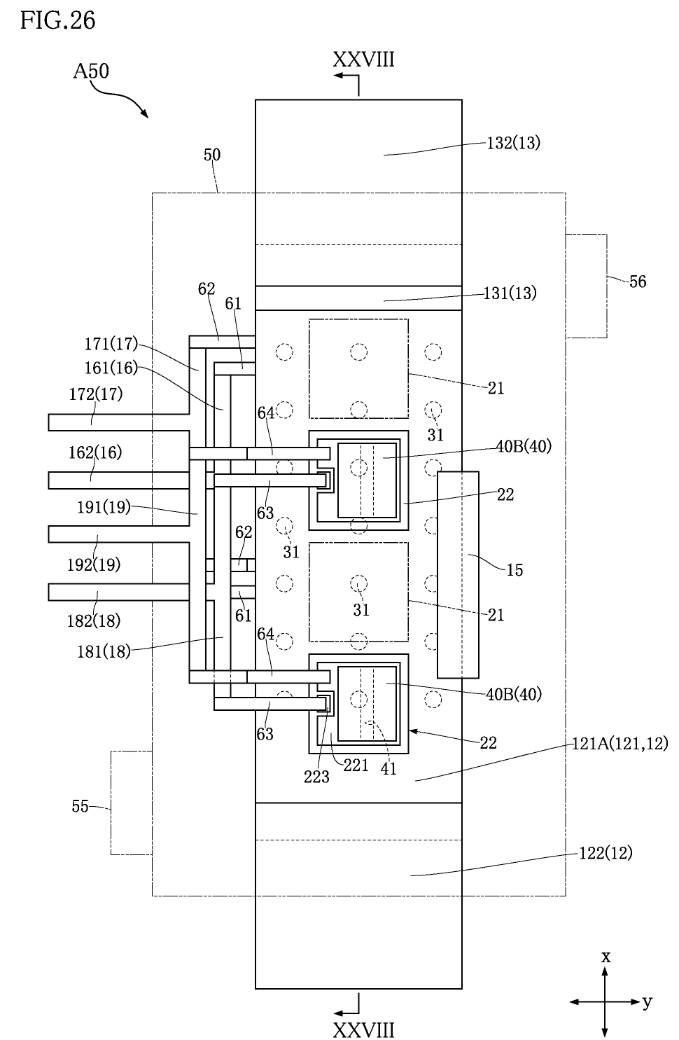

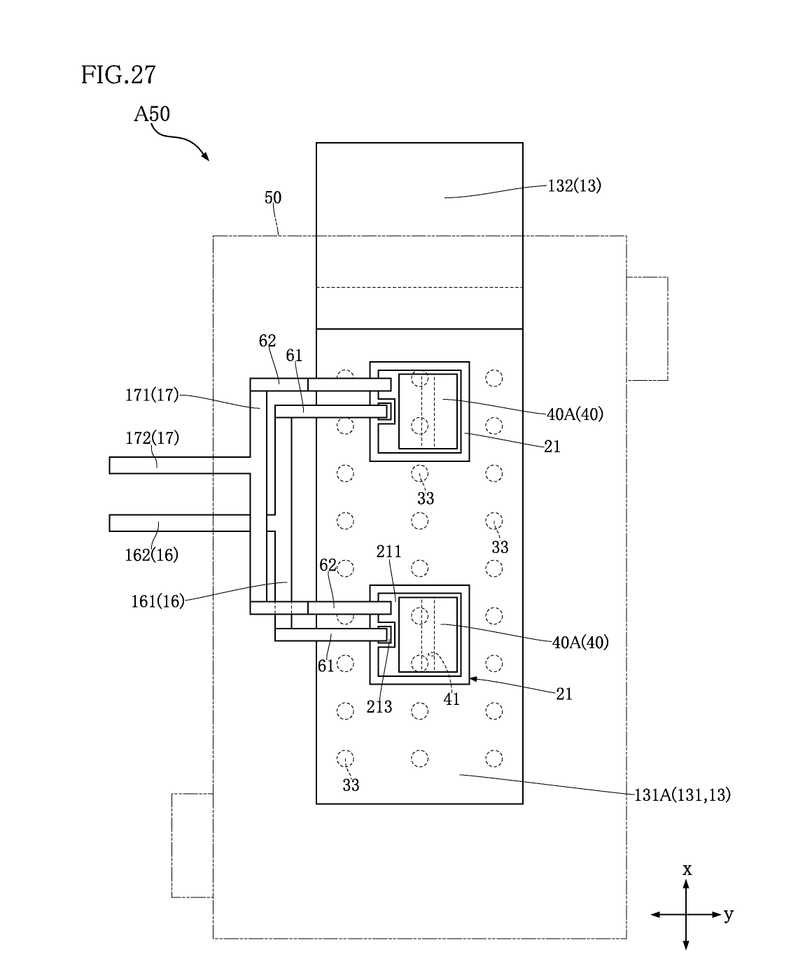

The following describes a semiconductor device A50 according to a fifth embodiment of the present disclosure, with reference to FIGS. 26-28. In these figures, elements that are identical or similar to those of the semiconductor device A10 are indicated by the same reference numerals, and overlapping descriptions are omitted. Note that FIG. 26 corresponds to FIG. 3 that shows the semiconductor device A10. FIG. 27 corresponds to FIG. 5 that shows the semiconductor device A10.

The semiconductor device A50 is different from the semiconductor device A10 in the configurations of the first semiconductor elements 21 and the second semiconductor elements 22.

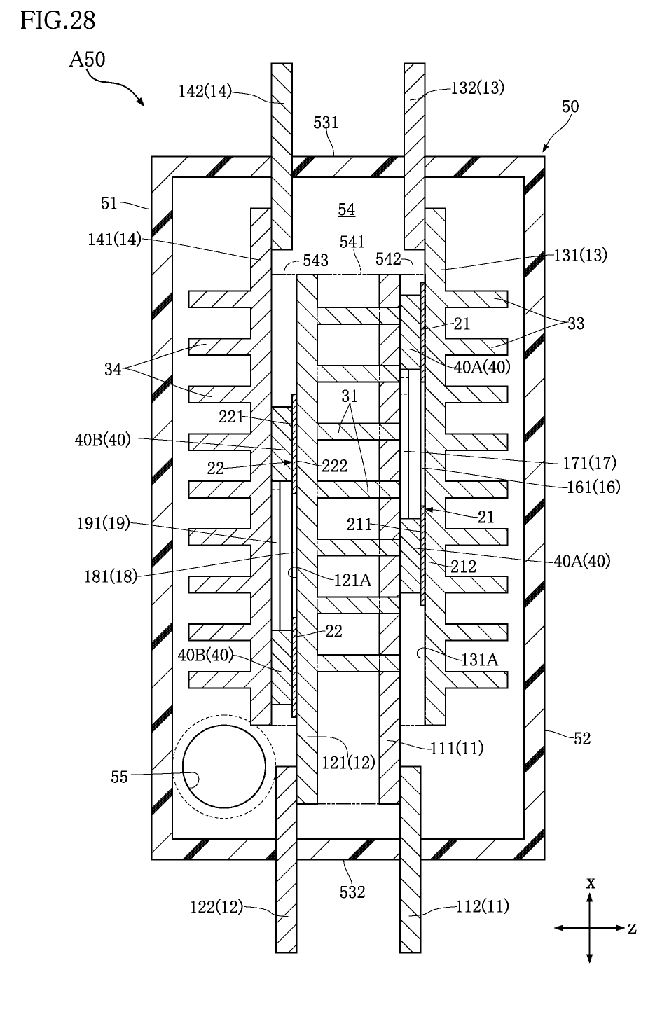

As shown in FIGS. 26 and 27, the number of first semiconductor elements 21 is two, and the number of second semiconductor elements 22 is also two. As shown in FIGS. 26 and 28, the second semiconductor elements 22 are spaced apart from the first semiconductor elements 21 as viewed in the first direction z.

The following describes advantages of the semiconductor device A50.

The semiconductor device A50 includes a first terminal 11, a second terminal 12, first semiconductor elements 21, and first heat dissipation members 31. The first semiconductor elements 21 are positioned opposite the second terminal 12 with respect to the first terminal 11 in the first direction z, and are electrically connected to the first terminal 11. The first heat dissipation members 31 are connected to the first terminal 11. In the first direction z, a first flow path 541 is provided between the first terminal 11 and the second terminal 12. The first heat dissipation members 31 are accommodated in the first flow path 541. Thus, with this configuration, it is possible to further improve the cooling efficiency of the semiconductor device A50. Further, the semiconductor device A50 has configurations similar to the semiconductor device A10, thereby achieving the same advantages as the semiconductor device A10.

In the semiconductor device A50, the second semiconductor elements 22 are spaced apart from the first semiconductor elements 21 as viewed in the first direction z. This configuration can reduce the concentration of thermal distribution in the second terminal 12 caused by heat generated in the first semiconductor elements 21 and the second semiconductor elements 22.

### Sixth Embodiment

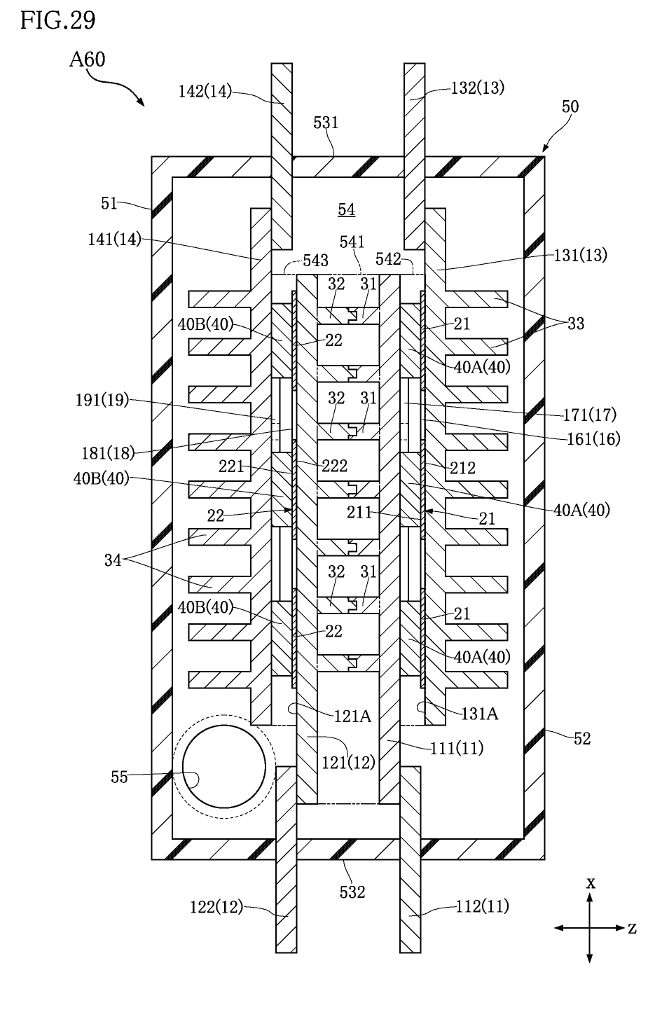

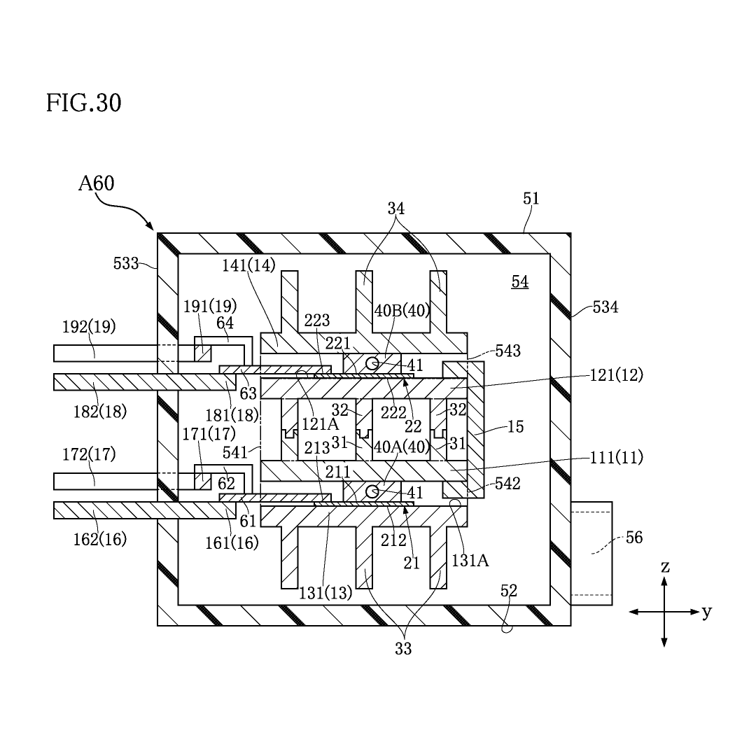

The following describes a semiconductor device A60 according to a sixth embodiment of the present disclosure, with reference to FIGS. 29-31. In these figures, elements that are identical or similar to those of the semiconductor device A10 are indicated by the same reference numerals, and overlapping descriptions are omitted. Note that FIG. 29 corresponds to FIG. 7 that shows the semiconductor device A10. FIG. 30 corresponds to FIG. 8 that shows the semiconductor device A10.

The semiconductor device A60 is different from the semiconductor device A10 in the configuration of the first heat dissipation members 31 and in further including a plurality of second heat dissipation members 32.

As shown in FIGS. 29 and 30, the first heat dissipation members 31 are connected to the first base 111 of the first terminal 11. The second heat dissipation members 32 are connected to the second base 121 of the second terminal 12. The first heat dissipation members 31 and the second heat dissipation members 32 are accommodated in the first flow path 541 of the cavity 54 of the housing 50. The second heat dissipation members 32 are rod members containing copper, for example. The second heat dissipation members 32 extend in the first direction z. In the semiconductor device A60, one end of each second heat dissipation member 32 in the first direction z is electrically bonded to the second base 121 by laser welding, for example.

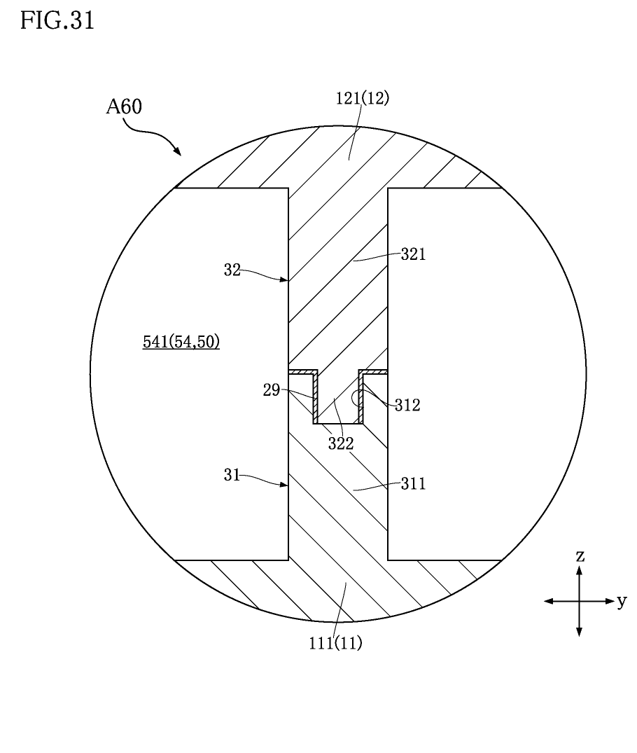

As shown in FIG. 31, each of the first heat dissipation members 31 has a first main portion 311 and a first engagement portion 312. The first main portion 311 is connected to the first base 111 of the first terminal 11. The first engagement portion 312 is recessed from the first main portion 311 on one side in the first direction z. Each of the second heat dissipation members 32 has a second main portion 321 and a second engagement portion 322. The second main portion 321 is connected to the second base 121 of the second terminal 12. The second engagement portion 322 protrudes from the second main portion 321 on one side in the first direction z. The second engagement portions 322 of the second heat dissipation members 32 are inserted in the first engagement portions 312 of the respective first heat dissipation members 31. The second engagement portions 322 of the second heat dissipation members 32 are electrically bonded to the respective first heat dissipation members 31 via bonding layers 29.

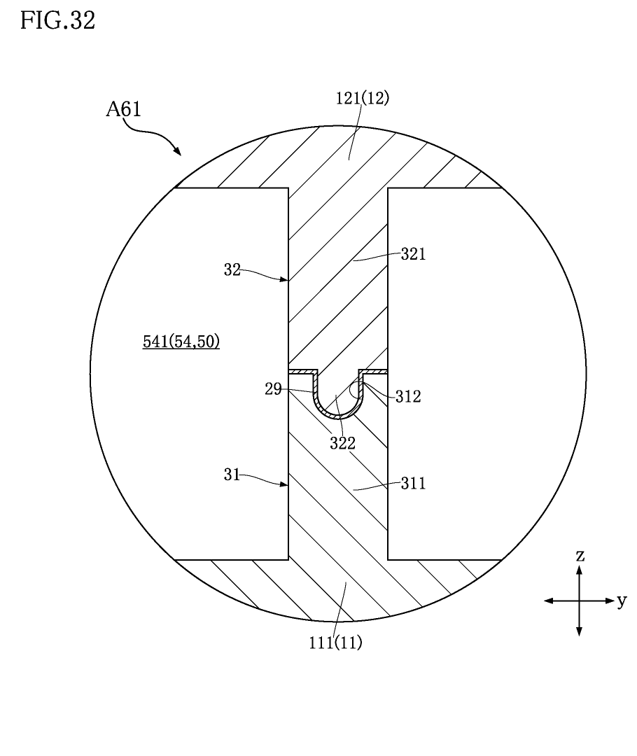

The following describes a semiconductor device A61 according to a variation of the sixth embodiment of the present disclosure, with reference to FIG. 32. Note that FIG. 32 corresponds to FIG. 31.

As shown in FIG. 32, the semiconductor device A61 is different from the semiconductor device A60 in the configurations of the first heat dissipation members 31 and the second heat dissipation members 32. The second engagement portion 322 of each second heat dissipation member 32 has a cross section perpendicular to the first direction z, and the area of the cross section decreases from the second main portion 321 toward the first main portion 311 of one of the first heat dissipation members 31. At least a portion of the first engagement portion 312 of each first heat dissipation member 31 and at least a portion of the second engagement portion 322 of each second heat dissipation member 32 are defined by curved surfaces.

The following describes advantages of the semiconductor device A60.

The semiconductor device A60 includes a first terminal 11, a second terminal 12, first semiconductor elements 21, and first heat dissipation members 31. The first semiconductor elements 21 are positioned opposite the second terminal 12 with respect to the first terminal 11 in the first direction z, and are electrically connected to the first terminal 11. The first heat dissipation members 31 are connected to the first terminal 11. In the first direction z, a first flow path 541 is provided between the first terminal 11 and the second terminal 12. The first heat dissipation members 31 are accommodated in the first flow path 541. Thus, with this configuration, it is possible to further improve the cooling efficiency of the semiconductor device A60. Further, the semiconductor device A60 has configurations similar to the semiconductor device A10, thereby achieving the same advantages as the semiconductor device A10.

The semiconductor device A60 further includes second heat dissipation members 32 connected to the second terminal 12. The second heat dissipation members 32 are accommodated in the first flow path 541. The second heat dissipation members 32 are connected to the first heat dissipation members 31. Each of the first heat dissipation members 31 has a first main portion 311 and a first engagement portion 312. Each of the second heat dissipation members 32 has a second main portion 321 and a second engagement portion 322. The second engagement portion 322 is inserted in the first engagement portion 312. This configuration can prevent misalignment of the second heat dissipation members 32 relative to the first heat dissipation members 31 when the second heat dissipation members 32 are connected to the first heat dissipation members 31.

### Seventh Embodiment

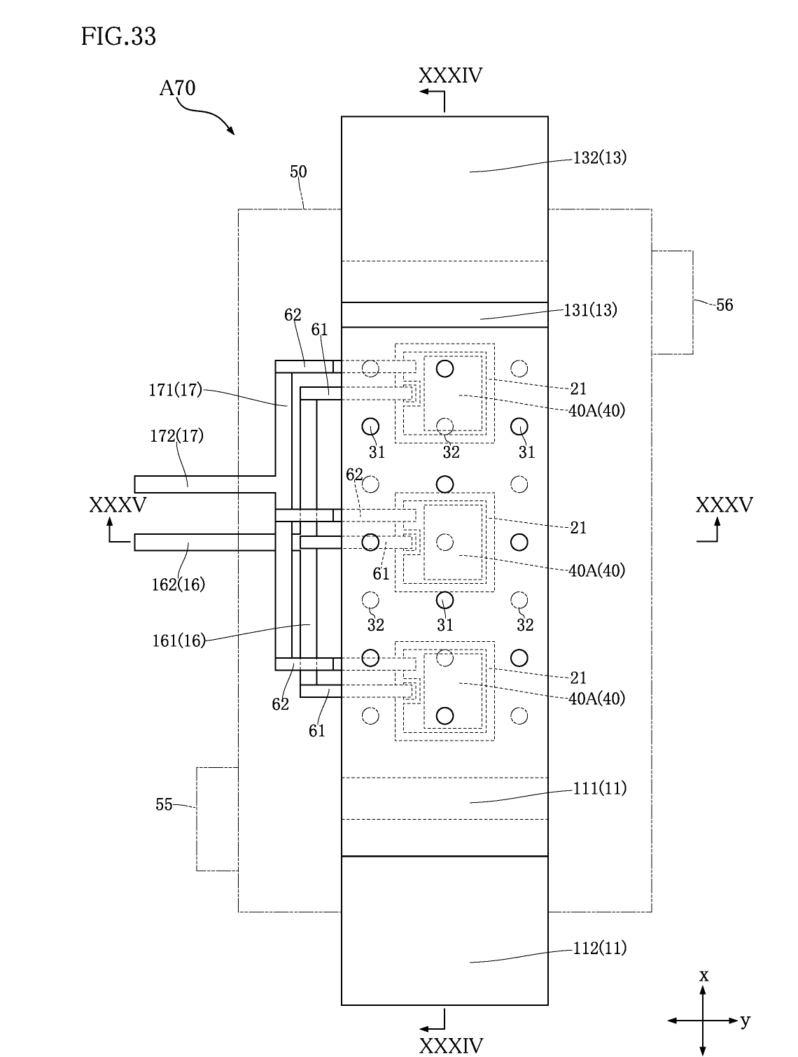

The following describes a semiconductor device A70 according to a seventh embodiment of the present disclosure, with reference to FIGS. 33-35. In these figures, elements that are identical or similar to those of the semiconductor device A10 are indicated by the same reference numerals, and overlapping descriptions are omitted. Note that FIG. 33 corresponds to FIG. 4 that shows the semiconductor device A10.

The semiconductor device A70 is different from the semiconductor device A60 in the configuration of the second heat dissipation members 32.

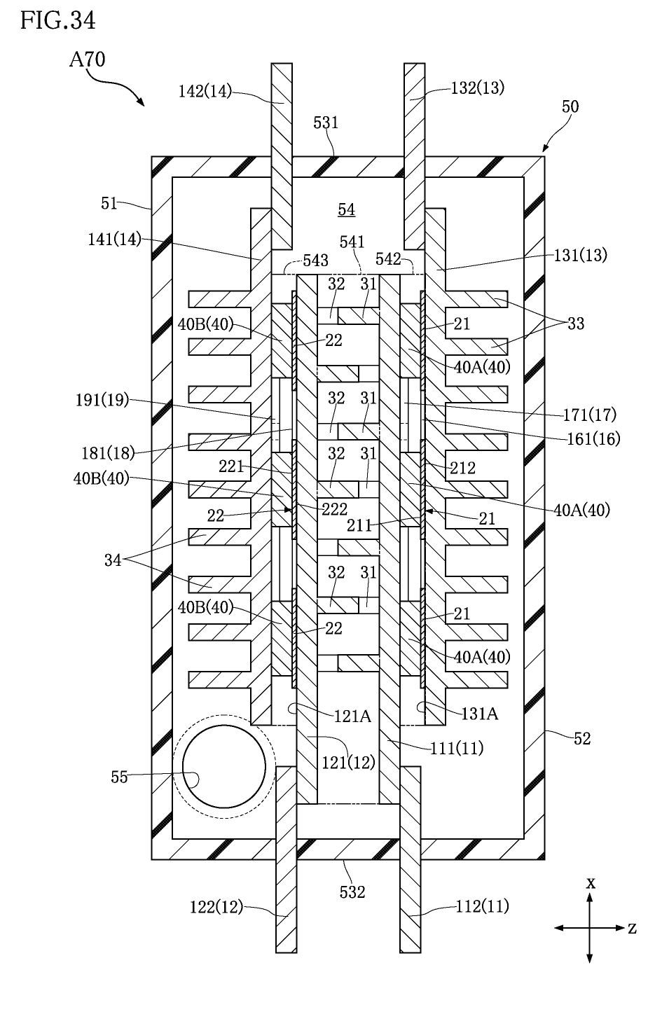

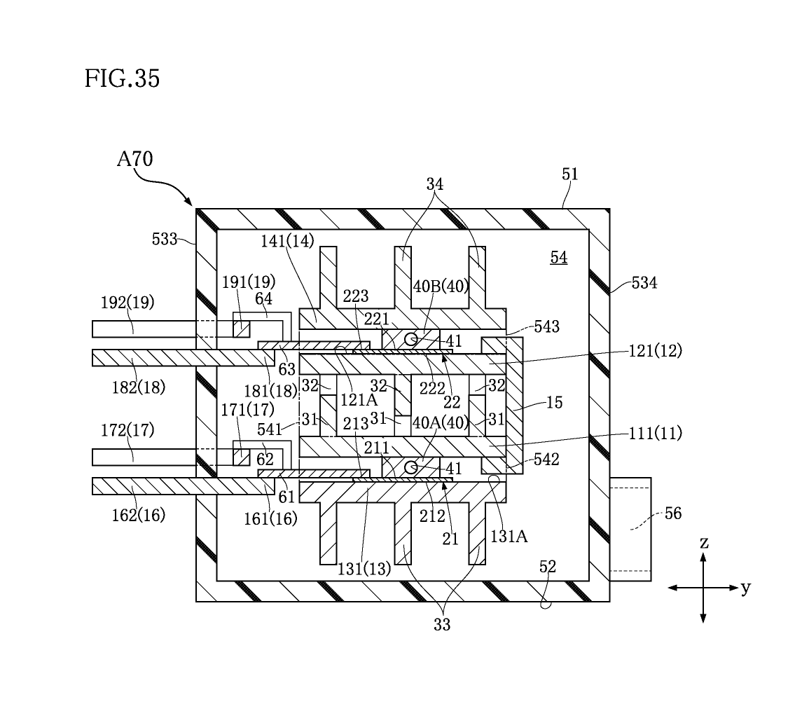

As shown in FIG. 33, the second heat dissipation members 32 are spaced apart from the first heat dissipation members 31 as viewed in the first direction z. As shown in FIGS. 34 and 35, the second heat dissipation members 32 are spaced apart from the first terminal 11.

The following describes advantages of the semiconductor device A70.

The semiconductor device A70 includes a first terminal 11, a second terminal 12, first semiconductor elements 21, and first heat dissipation members 31. The first semiconductor elements 21 are positioned opposite the second terminal 12 with respect to the first terminal 11 in the first direction z, and are electrically connected to the first terminal 11. The first heat dissipation members 31 are connected to the first terminal 11. In the first direction z, a first flow path 541 is provided between the first terminal 11 and the second terminal 12. The first heat dissipation members 31 are accommodated in the first flow path 541. Thus, with this configuration, it is possible to further improve the cooling efficiency of the semiconductor device A70. Further, the semiconductor device A70 has configurations similar to the semiconductor device A10, thereby achieving the same advantages as the semiconductor device A10.

In the semiconductor device A70, the second heat dissipation members 32 are spaced apart from the first heat dissipation members 31 as viewed in the first direction z. The second heat dissipation members 32 are spaced apart from the first terminal 11. This configuration can reduce the concentration of thermal distribution in the first terminal 11 and the second terminal 12 that is caused by heat generated in the first semiconductor elements 21 and the second semiconductor elements 22.

### Eighth Embodiment

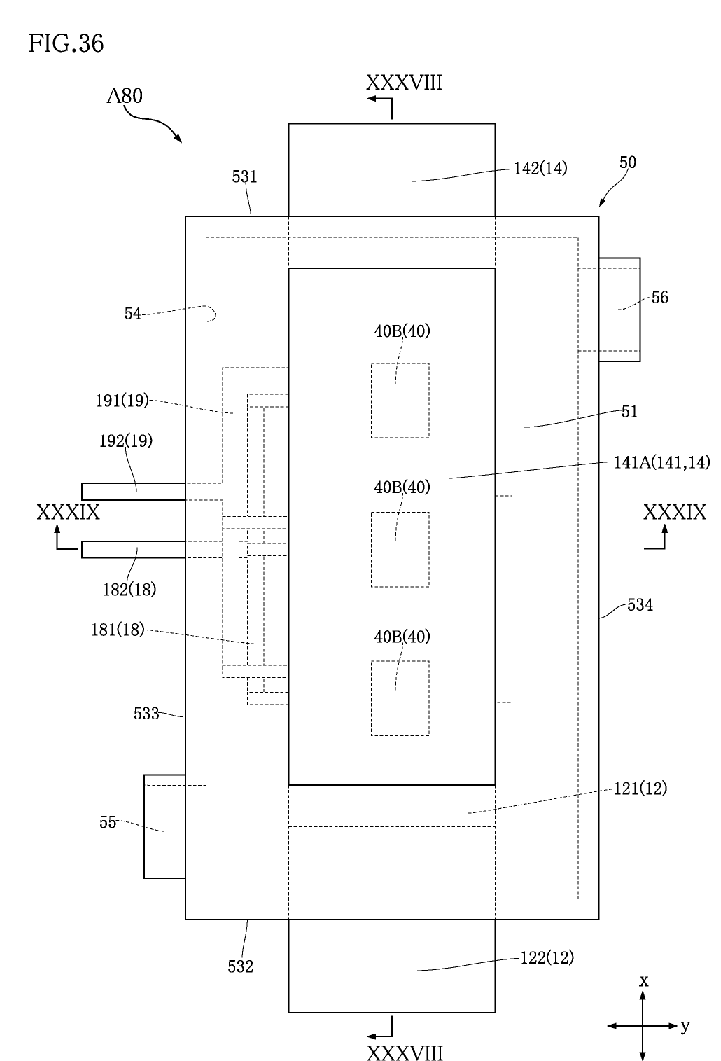

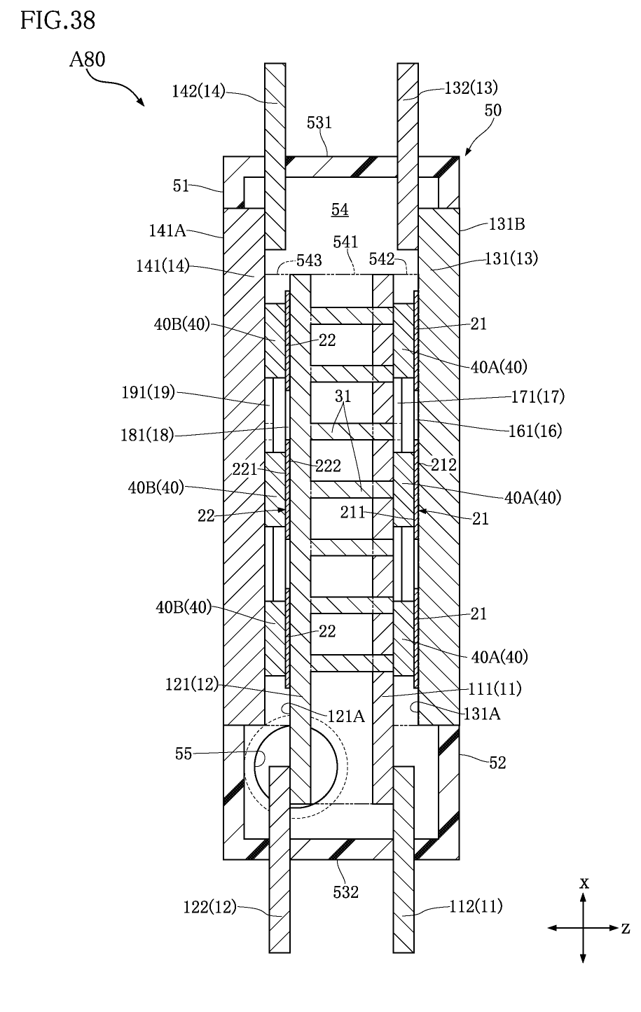

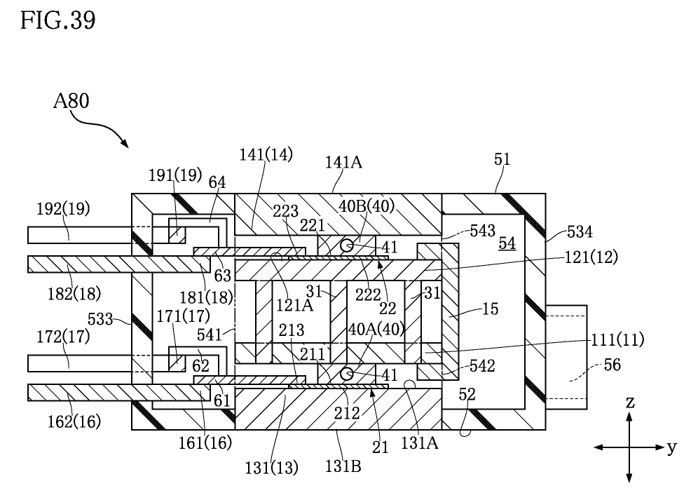

The following describes a semiconductor device A80 according to an eighth embodiment of the present disclosure, with reference to FIGS. 36-39. In these figures, elements that are identical or similar to those of the semiconductor device A10 are indicated by the same reference numerals, and overlapping descriptions are omitted.

The semiconductor device A80 is different from the semiconductor device A10 in the configurations of the third terminal 13 and the fourth terminal 14. Further, the semiconductor device A80 does not include the third heat dissipation members 33 and the fourth heat dissipation members 34.

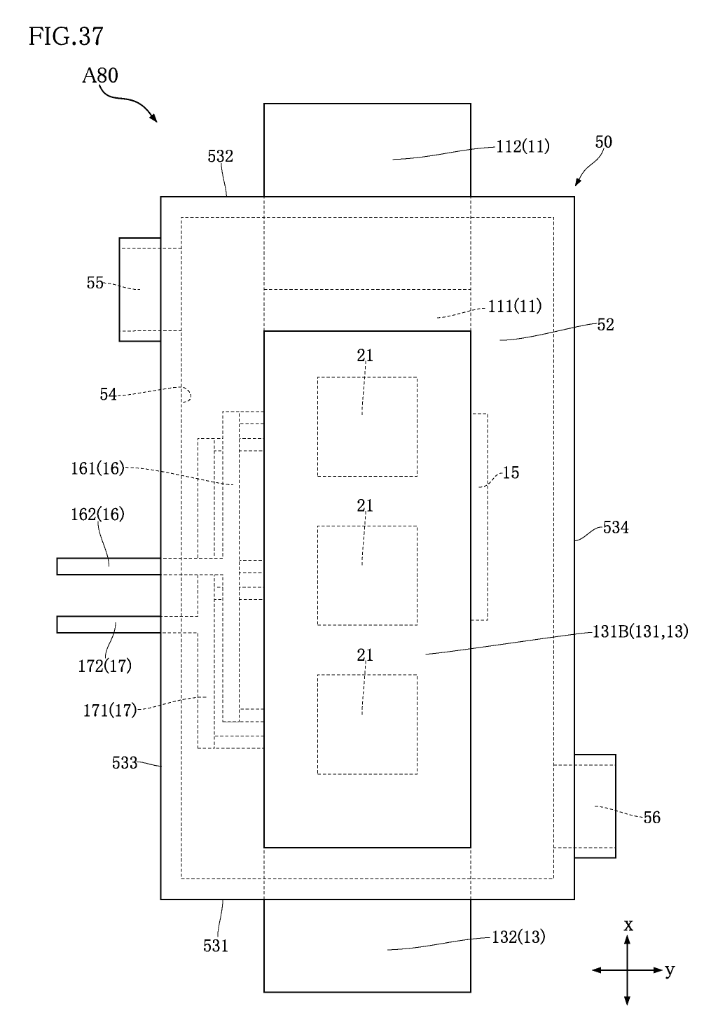

As shown in FIGS. 37-39, the third base 131 of the third terminal 13 has a first exposed surface 131B facing away from the first semiconductor elements 21 in the first direction z. The first exposed surface 131B is exposed from the bottom surface 52 of the housing 50. The dimension of the third base 131 in the first direction z is larger than the dimension of the first base 111 of the first terminal 11 in the first direction z.

As shown in FIGS. 36, 38, and 39, the fourth base 141 of the fourth terminal 14 has a second exposed surface 141A facing away from the second semiconductor elements 22 in the first direction z. The second exposed surface 141A is exposed from the top surface 51 of the housing 50. The dimension of the fourth base 141 in the first direction z is larger than the dimension of the second base 121 of the second terminal 12 in the first direction z.

The following describes advantages of the semiconductor device A80.

The semiconductor device A80 includes a first terminal 11, a second terminal 12, first semiconductor elements 21, and first heat dissipation members 31. The first semiconductor elements 21 are positioned opposite the second terminal 12 with respect to the first terminal 11 in the first direction z, and are electrically connected to the first terminal 11. The first heat dissipation members 31 are connected to the first terminal 11. In the first direction z, a first flow path 541 is provided between the first terminal 11 and the second terminal 12. The first heat dissipation members 31 are accommodated in the first flow path 541. Thus, with this configuration, it is possible to further improve the cooling efficiency of the semiconductor device A80. Further, the semiconductor device A80 has configurations similar to the semiconductor device A10, thereby achieving the same advantages as the semiconductor device A10.

In the semiconductor device A80, the third terminal 13 has a first exposed surface 131B facing away from the first semiconductor elements 21 in the first direction z. The fourth terminal 14 has a second exposed surface 141A facing away from the second semiconductor elements 22 in the first direction z. The first exposed surface 131B and the second exposed surface 141A are exposed from the housing 50. This configuration can further reduce the dimension of the semiconductor device A80 in the first direction z.

### Ninth Embodiment

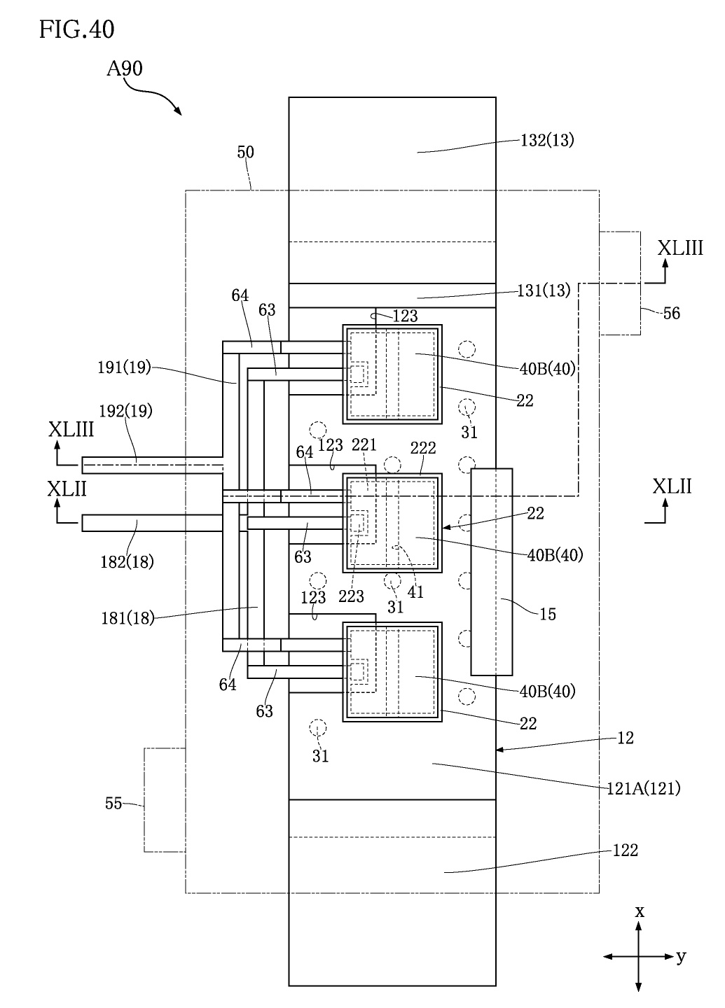

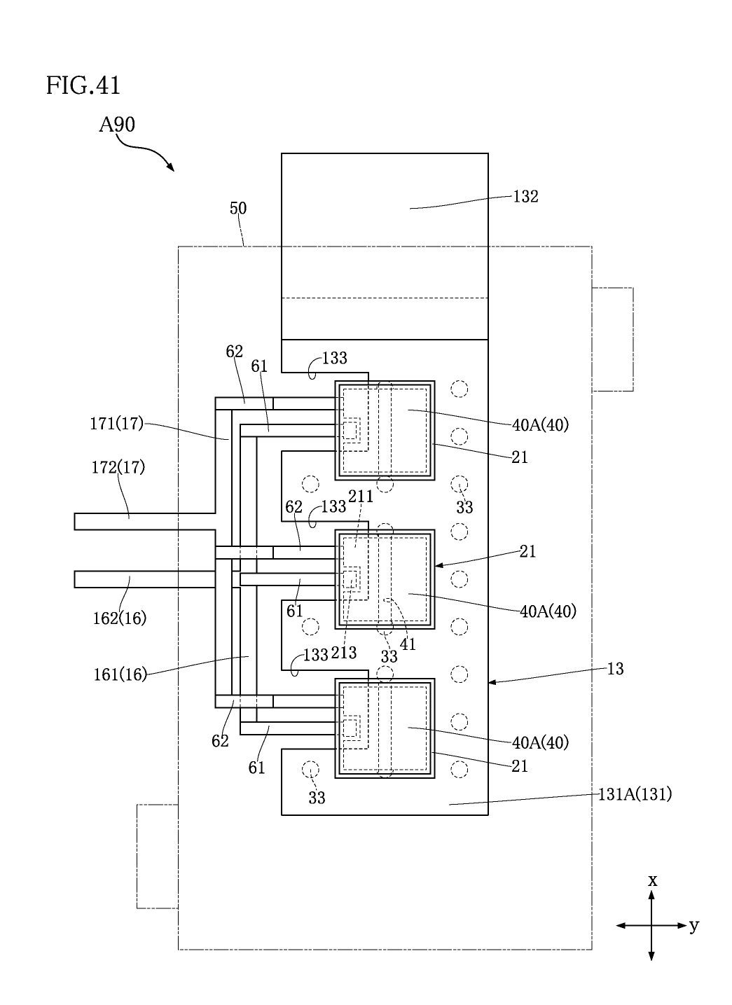

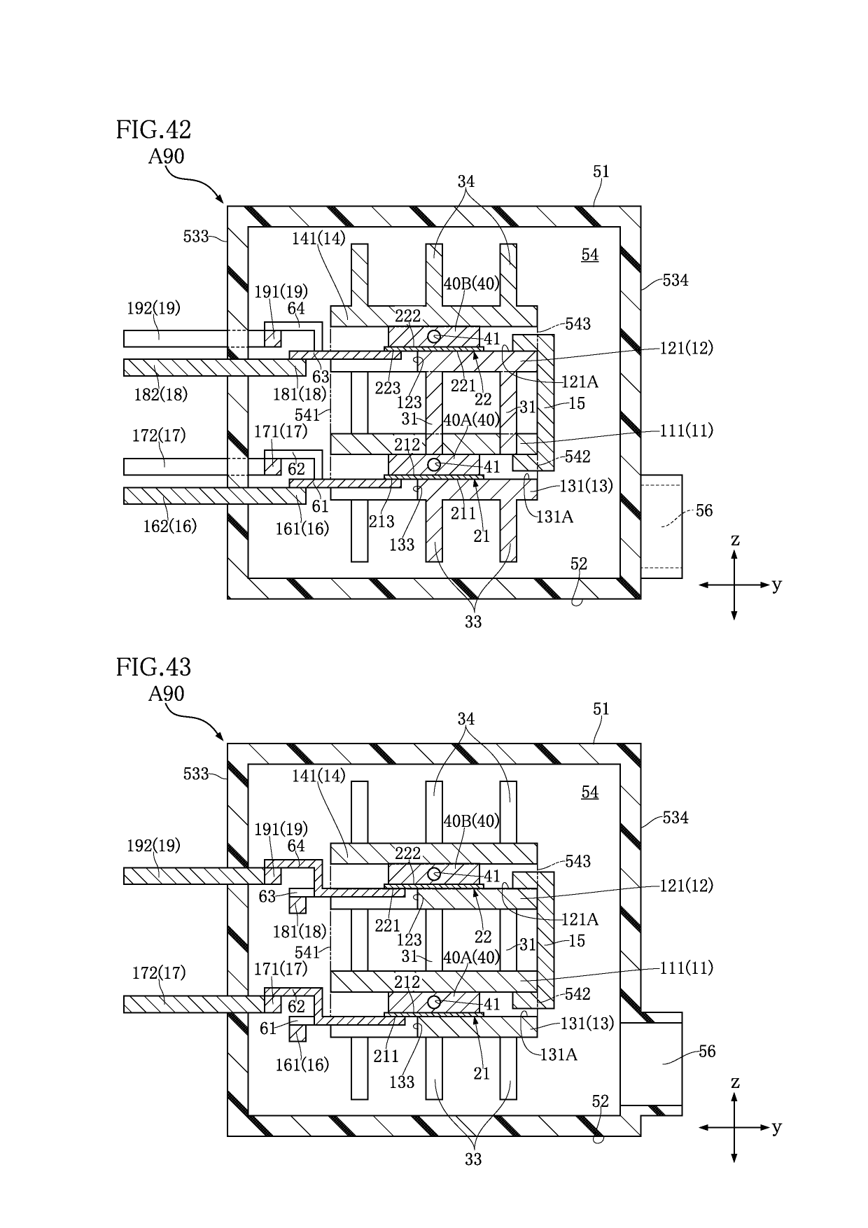

The following describes a semiconductor device A90 according to a ninth embodiment of the present disclosure, with reference to FIGS. 40-45. In these figures, elements that are identical or similar to those of the semiconductor device A10 are indicated by the same reference numerals, and overlapping descriptions are omitted. Note that FIG. 40 corresponds to FIG. 3 that shows the semiconductor device A10. FIG. 41 corresponds to FIG. 5 that shows the semiconductor device A10.

The semiconductor device A90 is different from the semiconductor device A10 in the configurations of the second terminal 12, the third terminal 13, the first semiconductor elements 21, and the second semiconductor elements 22.

As shown in FIGS. 41-43, the third base 131 of the third terminal 13 is provided with a plurality of first openings 133 that are recessed from one side in the third direction y and penetrate the third base 131 in the first direction z. As viewed in the first direction z, the first semiconductor elements 21 overlap with the respective first openings 133. A portion of each first lead 61 and a portion of each second lead 62 are accommodated in one of the first openings 133.

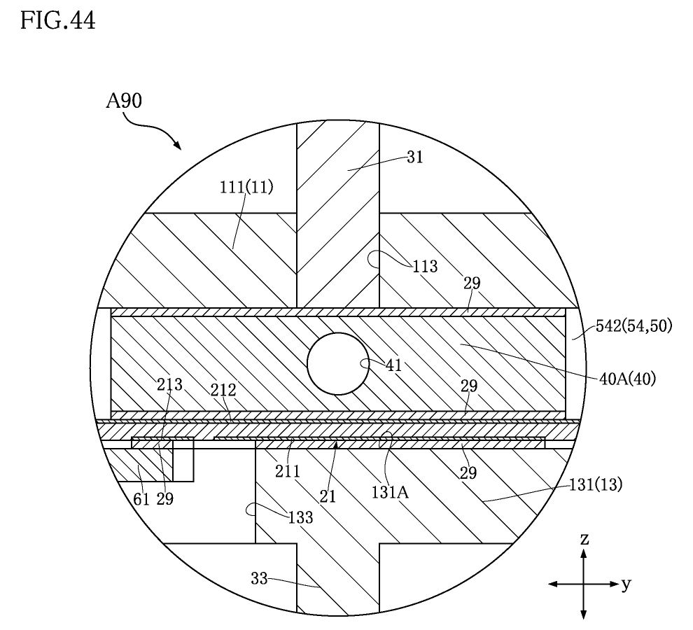

As shown in FIG. 44, the first electrode 211 of each first semiconductor element 21 is electrically bonded to the first mounting surface 131A of the third base 131 of the third terminal 13 via a bonding layer 29. The second electrode 212 of each first semiconductor element 21 is electrically bonded to one of the first spacers 40A via a bonding layer 29. As a result, the first electrodes 211 of the first semiconductor elements 21 are electrically connected to the third terminal 13. The second electrodes 212 of the first semiconductor elements 21 are electrically connected to the first terminal 11.

As shown in FIGS. 40, 42, and 43, the second base 121 of the second terminal 12 is provided with a plurality of second openings 123 that are recessed from one side in the third direction y and penetrate the second base 121 in the first direction z. As viewed in the first direction z, the second semiconductor elements 22 overlap with the respective second openings 123. A portion of each third lead 63 and a portion of each fourth lead 64 are accommodated in one of the second openings 123.

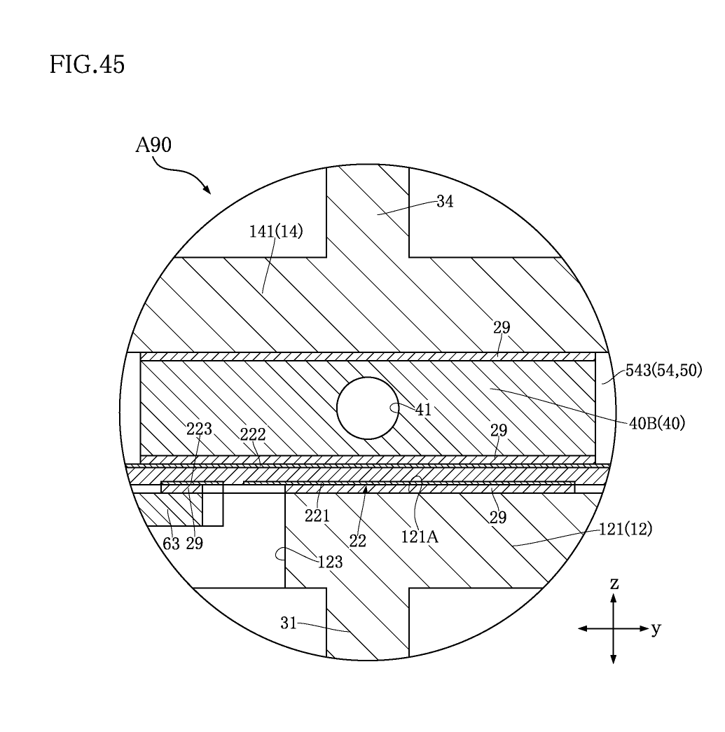

As shown in FIG. 45, the third electrode 221 of each second semiconductor element 22 is electrically bonded to the second mounting surface 121A of the second base 121 of the second terminal 12 via a bonding layer 29. The fourth electrode 222 of each second semiconductor element 22 is electrically bonded to one of the second spacers 40B via a bonding layer 29. As a result, the third electrodes 221 of the second semiconductor elements 22 are electrically connected to the second terminal 12. The fourth electrodes 222 of the second semiconductor elements 22 are electrically connected to the fourth terminal 14. Accordingly, in the semiconductor device A90, the fourth terminal 14 is a P terminal and the third terminal 13 is an N terminal.

The following describes advantages of the semiconductor device A90.

The semiconductor device A90 includes a first terminal 11, a second terminal 12, first semiconductor elements 21, and first heat dissipation members 31. The first semiconductor elements 21 are positioned opposite the second terminal 12 with respect to the first terminal 11 in the first direction z, and are electrically connected to the first terminal 11. The first heat dissipation members 31 are connected to the first terminal 11. In the first direction z, a first flow path 541 is provided between the first terminal 11 and the second terminal 12. The first heat dissipation members 31 are accommodated in the first flow path 541. Thus, with this configuration, it is possible to further improve the cooling efficiency of the semiconductor device A90. Further, the semiconductor device A90 has configurations similar to the semiconductor device A10, thereby achieving the same advantages as the semiconductor device A10.

### Tenth Embodiment

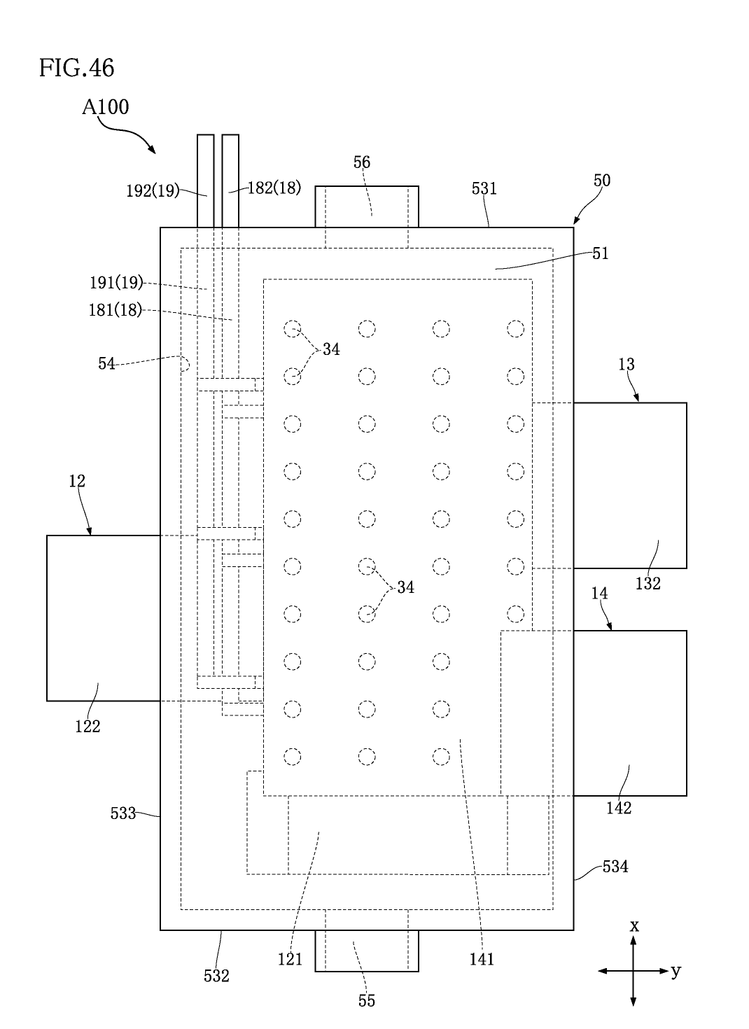

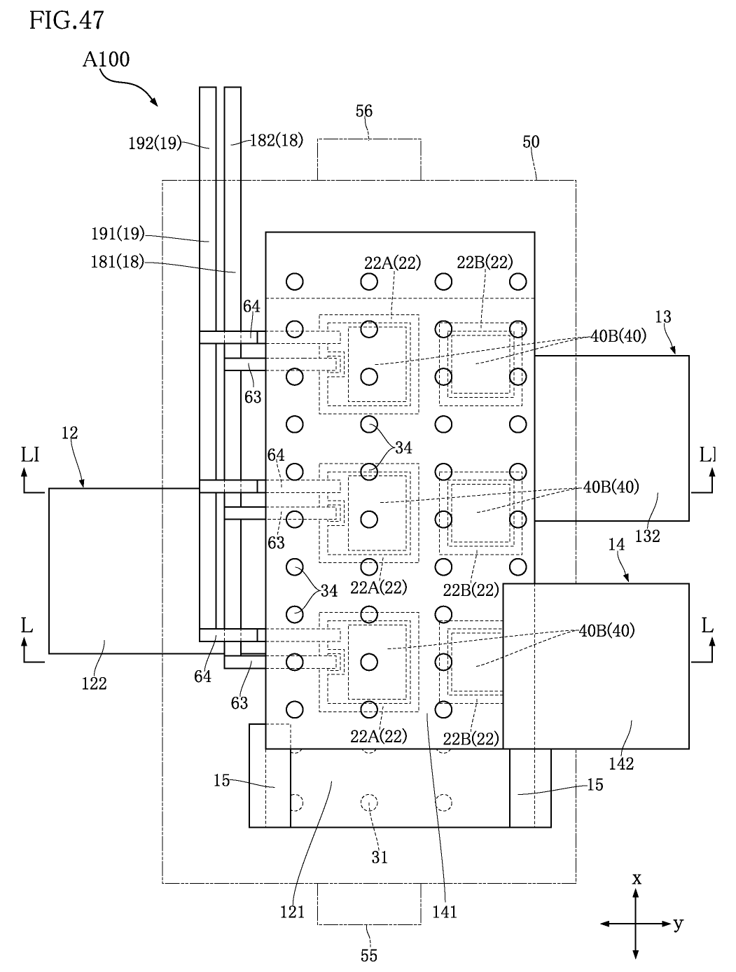

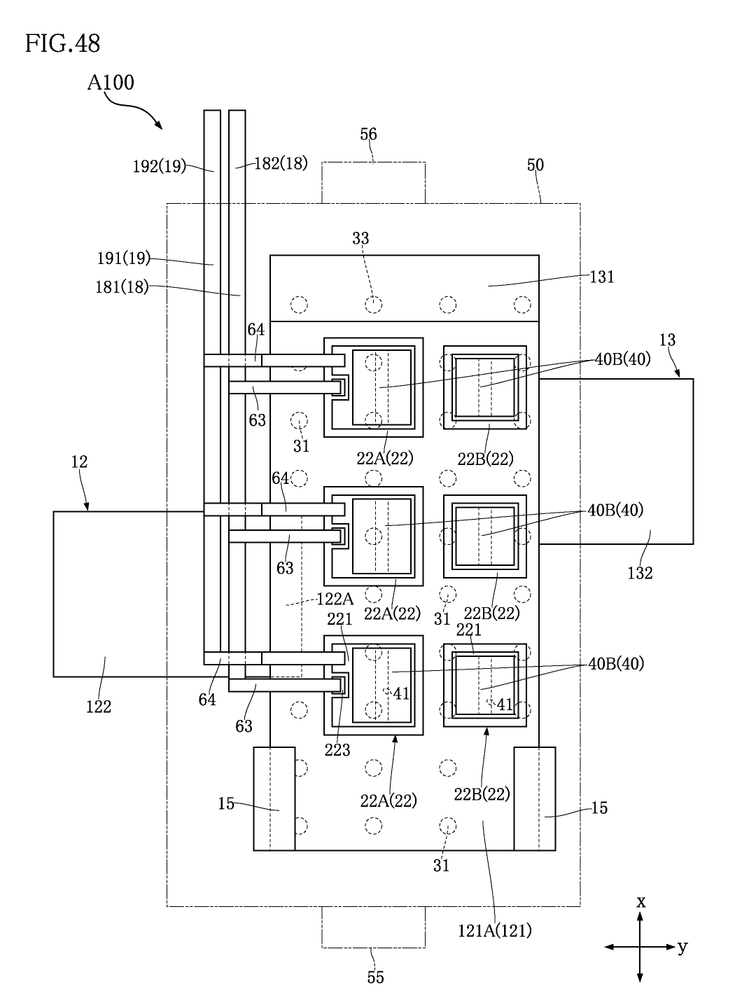

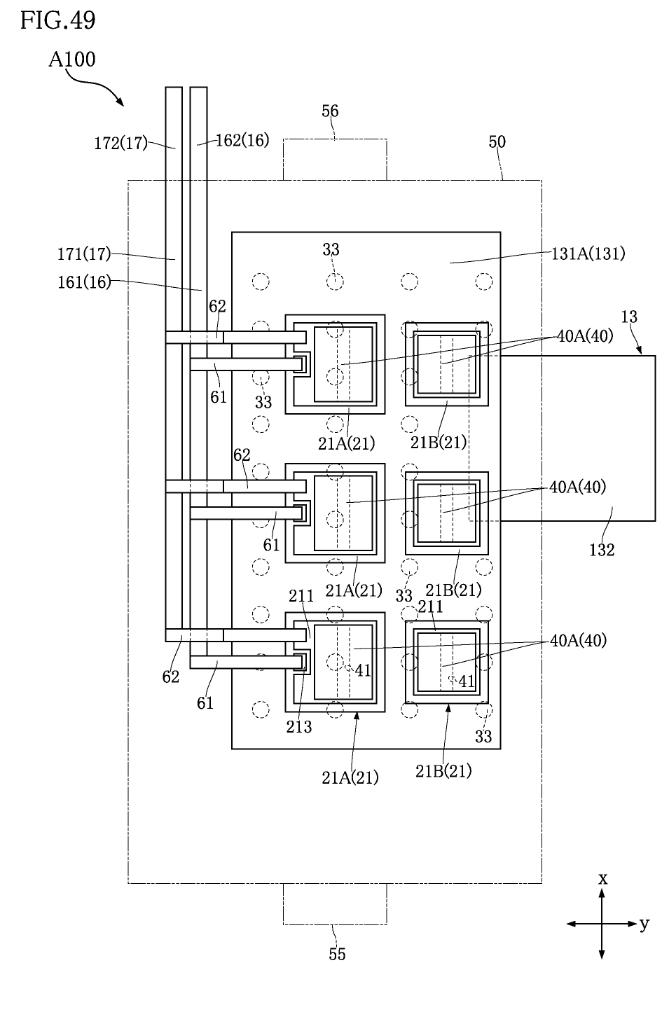

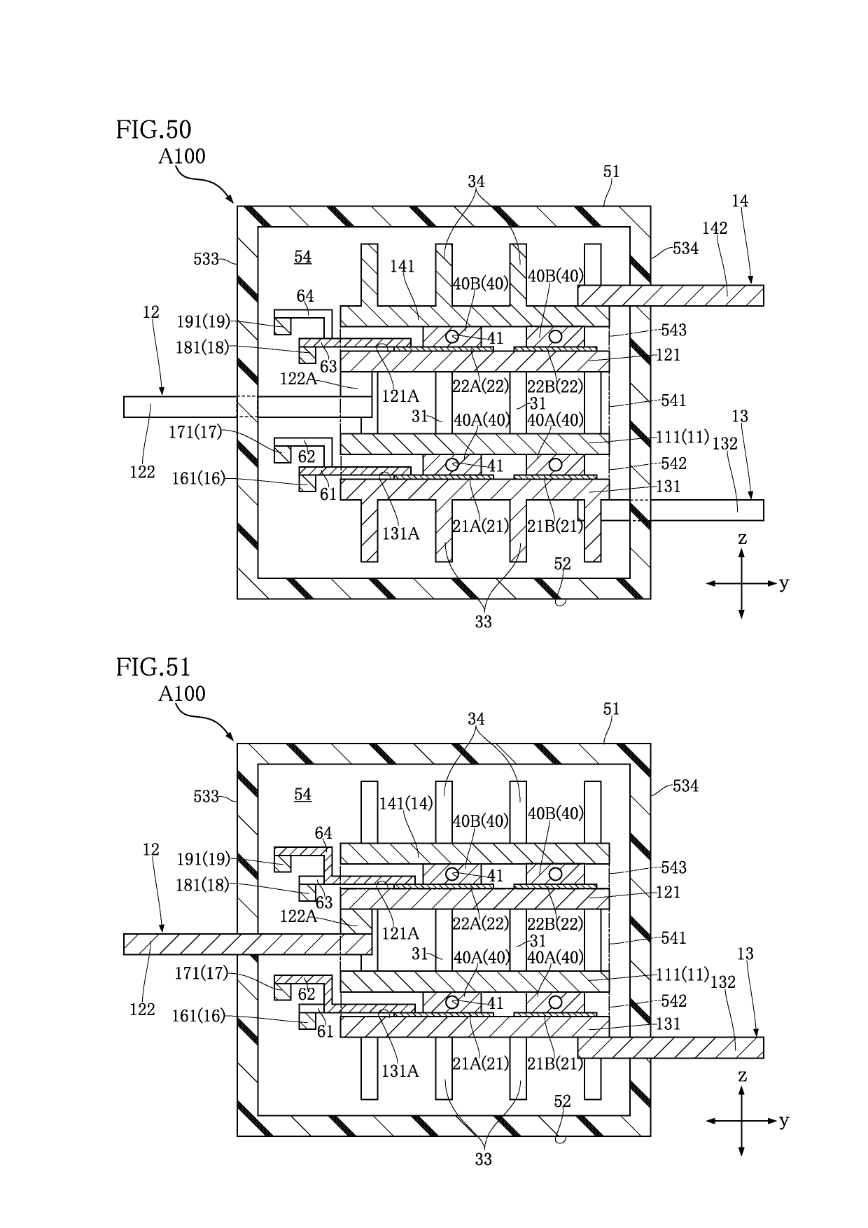

The following describes a semiconductor device A100 according to a tenth embodiment of the present disclosure, with reference to FIGS. 46-51. In these figures, elements that are identical or similar to those of the semiconductor device A10 are indicated by the same reference numerals, and overlapping descriptions are omitted. Note that FIG. 47 corresponds to FIG. 2 that shows the semiconductor device A10. FIG. 48 corresponds to FIG. 3 that shows the semiconductor device A10. FIG. 49 corresponds to FIG. 5 that shows the semiconductor device A10.

The semiconductor device A100 is different from the semiconductor device A10 in the configurations of the first terminal 11, the second terminal 12, the third terminal 13, the fourth terminal 14, the first signal terminal 16, the second signal terminal 17, the third signal terminal 18, the fourth signal terminal 19, the housing 50, the first semiconductor elements 21, and the second semiconductor elements 22. The semiconductor device A100 further includes two conductive members 15 instead of a single conductive member 15.

In the semiconductor device A100, the first terminal 11 does not include any first extension 112. As shown in FIGS. 48 and 51, the second extension 122 of the second terminal 12 is positioned on one side in the third direction y from the second base 121. The second extension 122 is electrically bonded to the second base 121 via a support 122A. As shown in FIGS. 46 and 51, the second extension 122 has a portion protruding outward from the third side surface 533 of the housing 50.

As shown in FIGS. 47, 49, and 50, the third extension 132 of the third terminal 13 and the fourth extension 142 of the fourth terminal 14 are positioned opposite the second extension 122 of the second terminal 12 with respect to the first semiconductor elements 21 and the second semiconductor elements 22 in the third direction y. As shown in FIGS. 46, 50, and 51, each of the third extension 132 and the fourth extension 142 has a portion protruding outward from the fourth side surface 534 of the housing 50. The third extension 132 and the fourth extension 142 are spaced apart from each other in the second direction x. As shown in FIG. 48, the two conductive members 15 are positioned on opposite sides of the first base 111 of the first terminal 11 and the second base 121 of the second terminal 12 in the third direction y.

As shown in FIGS. 46 and 49, the outer portion 162 of the first signal terminal 16 and the outer portion 172 of the second signal terminal 17 protrude outward from the first side surface 531 of the housing 50. As shown in FIG. 46, the outer portion 182 of the third signal terminal 18 and the outer portion 192 of the fourth signal terminal 19 protrude outward from the first side surface 531.

As shown in FIG. 46, the inlet 55 of the housing 50 is provided in the second side surface 532 of the housing 50. The outlet 56 of the housing 50 is provided in the first side surface 531.

As shown in FIGS. 49-51, the first semiconductor elements 21 include a plurality of first switching elements 21A and a plurality of first diodes 21B. The first diodes 21B are connected in parallel to the respective first switching elements 21A. Each of the first switching elements 21A has a first electrode 211, a second electrode 212, and a first gate electrode 213. The first switching elements 21A are transistors, such as MOSFETs or IGBTs. In the semiconductor device A100, the first switching elements 21A are MOSFETs, for example. Each of the first diodes 21B includes a first electrode 211 which is an anode, and a second electrode 212 which is a cathode. In the semiconductor device A100, the first diodes 21B function as freewheeling diodes for the first switching elements 21A. In the semiconductor device A100, the first diodes 21B are Schottky barrier diodes, for example. The first spacers 40A are electrically bonded to the respective first electrodes 211 of the first switching elements 21A and the first diodes 21B.

As shown in FIGS. 48, 50, and 51, the second semiconductor elements 22 include a plurality of second switching elements 22A and a plurality of second diodes 22B. The second diodes 22B are connected in parallel to the respective second switching elements 22A. Each of the second switching elements 22A has a third electrode 221, a fourth electrode 222, and a second gate electrode 223. The second switching elements 22A are identical to the first switching elements 21A. Each of the second diodes 22B has a third electrode 221 which is an anode, and a fourth electrode 222 which is a cathode. In the semiconductor device A100, the second diodes 22B function as freewheeling diodes for the second switching elements 22A. The second diodes 22B are identical to the first diodes 21B. The second spacers 40B are electrically bonded to the respective third electrodes 221 of the second switching elements 22A and the second diodes 22B.

Thus, as in the semiconductor device A100, the first semiconductor elements 21 may not be all identical, but may include different types of elements. Similarly, the second semiconductor elements 22 may not be all identical, but may include different types of elements.

The following describes advantages of the semiconductor device A100.

The semiconductor device A100 includes a first terminal 11, a second terminal 12, first semiconductor elements 21, and first heat dissipation members 31. The first semiconductor elements 21 are positioned opposite the second terminal 12 with respect to the first terminal 11 in the first direction z, and are electrically connected to the first terminal 11. The first heat dissipation members 31 are connected to the first terminal 11. In the first direction z, a first flow path 541 is provided between the first terminal 11 and the second terminal 12. The first heat dissipation members 31 are accommodated in the first flow path 541. Thus, with this configuration, it is possible to further improve the cooling efficiency of the semiconductor device A100. Further, the semiconductor device A100 has configurations similar to the semiconductor device A10, thereby achieving the same advantages as the semiconductor device A10.

The present disclosure is not limited to the above embodiments. Various design changes can be made to the specific configurations of the elements in the present disclosure.

The present disclosure includes the embodiments described in the following clauses.

Clause 1. A semiconductor device comprising:

a first terminal;

a second terminal positioned on one side in a first direction from the first terminal;

a first semiconductor element positioned opposite the second terminal with respect to the first terminal and electrically connected to the first terminal; and

a first heat dissipation member connected to the first terminal,

wherein a first flow path is provided between the first terminal and the second terminal in the first direction, and

the first heat dissipation member is accommodated in the first flow path.

Clause 2. The semiconductor device according to clause 1, wherein the first terminal and the second terminal are in contact with the first flow path.

Clause 3. The semiconductor device according to clause 2, wherein the first heat dissipation member is spaced apart from the second terminal.

Clause 4. The semiconductor device according to clause 3, further comprising a second heat dissipation member connected to the second terminal,

wherein the second heat dissipation member is accommodated in the first flow path.

Clause 5. The semiconductor device according to clause 4, wherein the second heat dissipation member is connected to the first heat dissipation member.

Clause 6. The semiconductor device according to clause 5, wherein the first heat dissipation member includes a first main portion connected to the first terminal, and a first engagement portion recessed from the first main portion on one side in the first direction,

the second heat dissipation member includes a second main portion connected to the second terminal, and a second engagement portion protruding from the second main portion on one side in the first direction, and

the second engagement portion is inserted in the first engagement portion.

Clause 7. The semiconductor device according to clause 4, wherein the second heat dissipation member is spaced apart from the first heat dissipation member as viewed in the first direction.

Clause 8. The semiconductor device according to clause 7, wherein the second heat dissipation member is spaced apart from the first terminal.

Clause 9. The semiconductor device according to clause 2, wherein the first heat dissipation member is connected to the second terminal.

Clause 10. The semiconductor device according to clause 9, wherein at least one of the first terminal and the second terminal is provided with a support portion that penetrates therethrough in the first direction, and

the first heat dissipation member has a portion inserted in the support portion.

Clause 11. The semiconductor device according to any one of clauses 2 to 10, further comprising a third terminal positioned opposite the first terminal with respect to the first semiconductor element,

wherein the first semiconductor element is electrically connected to the third terminal,

a second flow path is provided between the first terminal and the third terminal in the first direction, and

the first semiconductor element is accommodated in the second flow path.

Clause 12. The semiconductor device according to clause 11, wherein the third terminal is in contact with the second flow path.

Clause 13. The semiconductor device according to clause 12, further comprising a first spacer electrically bonded to the first terminal and the first semiconductor element,

the first spacer is accommodated in the second flow path, and

a dimension of the first spacer in the first direction is larger than a dimension of the first semiconductor element in the first direction.

Clause 14. The semiconductor device according to clause 13, wherein the first spacer is provided with a through portion that penetrates the first spacer in a direction perpendicular to the first direction.

Clause 15. The semiconductor device according to clause 13, wherein the first spacer includes a peripheral surface facing a direction perpendicular to the first direction, and

the first spacer is provided with a groove that is recessed from the peripheral surface and that extends in a direction perpendicular to the first direction.

Clause 16. The semiconductor device according to clause 13, wherein the first semiconductor element is electrically bonded to the third terminal.

Clause 17. The semiconductor device according to clause 16, further comprising a housing,

wherein the first terminal, the second terminal, and the third terminal are supported by the housing, and

the housing is provided with a cavity that includes the first flow path and the second flow path.

Clause 18. The semiconductor device according to clause 17, further comprising a third heat dissipation member connected to the third terminal,

the third heat dissipation member is positioned opposite the first semiconductor element with respect to the third terminal, and

the third heat dissipation member is accommodated in the cavity.

Clause 19. The semiconductor device according to clause 17, further comprising a conductive member electrically bonded to the first terminal and the second terminal, and

the conductive member is accommodated in the cavity.

Clause 20. A vehicle comprising:

a drive source; and

the semiconductor device according to clause 11,

wherein the semiconductor device is electrically connected to the drive source.

Clause 21. The semiconductor device according to clause 2, wherein the first heat dissipation member extends in the first direction, and

the first heat dissipation member has a cross section perpendicular to the first direction, and an area of the cross section increases from the first terminal toward the second terminal.

Clause 22. The semiconductor device according to clause 6, wherein the second engagement portion has a cross section perpendicular to the first direction, and an area of the cross section decreases from the second main portion toward the first main portion.

Clause 23. The semiconductor device according to clause 22, wherein at least a portion of each of the first engagement portion and the second engagement portion is defined by a curved surface.

Clause 24. The semiconductor device according to clause 13, wherein the first spacer includes a first pedestal electrically bonded to the first semiconductor element, and a plurality of pillars positioned opposite the first semiconductor element with respect to the first pedestal in the first direction,

the plurality of pillars are spaced apart from each other in a direction perpendicular to the first direction z, and

the plurality of pillars are electrically connected to the first pedestal, and are in electrical conduction with the first terminal.

Clause 25. The semiconductor device according to clause 16, further comprising a second semiconductor element positioned opposite the first terminal with respect to the second terminal,

wherein the second terminal is electrically connected to the first terminal, and

the second semiconductor element is electrically bonded to the second terminal.

Clause 26. The semiconductor device according to clause 25, wherein as viewed in the first direction, the second semiconductor element overlaps with the first semiconductor element.

Clause 27. The semiconductor device according to clause 25, wherein as viewed in the first direction, the second semiconductor element is spaced apart from the first semiconductor element.

Clause 28. The semiconductor device according to clause 25, further comprising a fourth terminal positioned opposite the second terminal with respect to the second semiconductor element,

a third flow path is provided between the second terminal and the fourth terminal in the first direction, and

the second semiconductor element is accommodated in the third flow path.

Clause 29. The semiconductor device according to clause 28, wherein the fourth terminal is in contact with the third flow path.

Clause 30. The semiconductor device according to clause 29, wherein the first semiconductor element is in contact with the second flow path, and

the second semiconductor element is in contact with the third flow path.

Clause 31. The semiconductor device according to clause 29, further comprising a second spacer electrically bonded to the fourth terminal and the second semiconductor element,

the second spacer is accommodated in the third flow path, and

a dimension of the second spacer in the first direction is larger than a dimension of the second semiconductor element in the first direction.

Clause 32. The semiconductor device according to clause 16, further comprising a first signal terminal,

wherein the first semiconductor element includes a first electrode and a second electrode positioned opposite each other in the first direction, and a first gate electrode positioned on a same side as the first electrode in the first direction,

the first electrode is electrically bonded to the first spacer,

the second electrode is electrically bonded to the third terminal, and

the first gate electrode is electrically connected to the first signal terminal.

Clause 33. The semiconductor device according to clause 17, wherein the housing includes an inlet and an outlet that are in communication with the cavity, and

the inlet and the outlet are positioned opposite each other with respect to the first heat dissipation member in a direction perpendicular to the first direction.

Clause 34. The semiconductor device according to clause 33, wherein the third terminal includes a first exposed surface facing away from the first semiconductor element in the first direction, and

the first exposed surface is exposed from the housing.

1. A semiconductor device comprising:
a first terminal;
a second terminal positioned to one side in a first direction with respect to the first terminal;
a first semiconductor element positioned opposite the second terminal with respect to the first terminal and electrically connected to the first terminal; and
a first heat dissipation member connected to the first terminal,
wherein a first flow path is provided between the first terminal and the second terminal in the first direction, and
the first heat dissipation member is accommodated in the first flow path.

2. The semiconductor device according to claim 1, wherein the first terminal and the second terminal are in contact with the first flow path.

3. The semiconductor device according to claim 2, wherein the first heat dissipation member is spaced apart from the second terminal.

4. The semiconductor device according to claim 3, further comprising a second heat dissipation member connected to the second terminal,
wherein the second heat dissipation member is accommodated in the first flow path.

5. The semiconductor device according to claim 4, wherein the second heat dissipation member is connected to the first heat dissipation member.

6. The semiconductor device according to claim 5, wherein the first heat dissipation member includes a first main portion connected to the first terminal, and a first engagement portion recessed from one side of the first main portion in the first direction,
the second heat dissipation member includes a second main portion connected to the second terminal, and a second engagement portion protruding from one side of the second main portion in the first direction, and
the second engagement portion is inserted in the first engagement portion.

7. The semiconductor device according to claim 4, wherein the second heat dissipation member is spaced apart from the first heat dissipation member as viewed in the first direction.

8. The semiconductor device according to claim 7, wherein the second heat dissipation member is spaced apart from the first terminal.

9. The semiconductor device according to claim 2, wherein the first heat dissipation member is connected to the second terminal.

10. The semiconductor device according to claim 9, wherein at least one of the first terminal and the second terminal is provided with a support portion that penetrates therethrough in the first direction, and
the first heat dissipation member has a portion inserted in the support portion.

11. The semiconductor device according to claim 2, further comprising a third terminal positioned opposite the first terminal with respect to the first semiconductor element,
wherein the first semiconductor element is electrically connected to the third terminal,
a second flow path is provided between the first terminal and the third terminal in the first direction, and
the first semiconductor element is accommodated in the second flow path.

12. The semiconductor device according to claim 11, wherein the third terminal is in contact with the second flow path.

13. The semiconductor device according to claim 12, further comprising a first spacer electrically bonded to the first terminal and the first semiconductor element,
the first spacer is accommodated in the second flow path, and
a dimension of the first spacer in the first direction is larger than a dimension of the first semiconductor element in the first direction.

14. The semiconductor device according to claim 13, wherein the first spacer is provided with a through portion that penetrates the first spacer in a direction perpendicular to the first direction.

15. The semiconductor device according to claim 13, wherein the first spacer includes a peripheral surface facing a direction perpendicular to the first direction, and
the first spacer is provided with a groove that is recessed from the peripheral surface and that extends in a direction perpendicular to the first direction.

16. The semiconductor device according to claim 13, wherein the first semiconductor element is electrically bonded to the third terminal.

17. The semiconductor device according to claim 16, further comprising a housing,
wherein the first terminal, the second terminal, and the third terminal are supported by the housing, and
the housing is provided with a cavity that includes the first flow path and the second flow path.

18. The semiconductor device according to claim 17, further comprising a third heat dissipation member connected to the third terminal,
the third heat dissipation member is positioned opposite the first semiconductor element with respect to the third terminal, and
the third heat dissipation member is accommodated in the cavity.

19. The semiconductor device according to claim 17, further comprising a conductive member electrically bonded to the first terminal and the second terminal, and
the conductive member is accommodated in the cavity.

20. A vehicle comprising:
a drive source; and
the semiconductor device according to claim 11,
wherein the semiconductor device is electrically connected to the drive source.
